(19) United States
(12) Patent Application Publication
(10) Pub. No.: US 2023/0369535 A1
(43) Pub. Date: Nov. 16, 2023

(54) NANOWIRE ARCHITECTURE FOR MICRO-DISPLAYS

(71) Applicant: Meta Platforms Technologies, LLC, Menlo Park, CA (US)

(72) Inventors: Wei Sin TAN, Plymouth (GB); Andrea PINOS, Plymouth (GB); Samir MEZOUARI, Swindon (GB)

(21) Appl. No.: 17/741,245

(22) Filed: May 10, 2022

(51) Int. Cl. H01L 33/06; H01L 25/075; H01L 33/00; H01L 33/58

(52) U.S. Cl. CPC H01L 33/06; H01L 25/0753; H01L 33/0095; H01L 33/58; G02B 27/0172

(57) ABSTRACT

A light source includes an array of core-shell nanowire micro-LEDs. Each core-shell nanowire micro-LED includes: a first semiconductor epitaxial layer including a nanowire core formed therein; a first dielectric material layer in physical contact with and surrounding sidewalls of a bottom portion of the nanowire core, or in physical contact with a bottom surface of the nanowire core; a second dielectric material layer in physical contact with a top surface of the nanowire core; active layers grown only on sidewalls of the nanowire core and configured to emit visible light; and a second semiconductor layer grown on the active layers, where the nanowire core and the second semiconductor layer are oppositely doped.

### BACKGROUND

Light emitting diodes (LEDs) convert electrical energy into optical energy, and offer many benefits over other light sources, such as reduced size, improved durability, and increased efficiency. LEDs can be used as light sources in many display systems, such as televisions, computer monitors, laptop computers, tablets, smartphones, projection systems, and wearable electronic devices. Micro-LEDs (“μLEDs”) based on III-V semiconductors, such as alloys of AlN, GaN, InN, AlGaInP, other ternary and quaternary nitride, phosphide, and arsenide compositions, have begun to be developed for various display applications due to their small size (e.g., with a linear dimension less than 100 μm, less than 50 μm, less than 10 μm, or less than 5 μm), high packing density (and hence higher resolution), and high brightness. For example, micro-LEDs that emit light of different colors (e.g., red, green, and blue) can be used to form the sub-pixels of a display system, such as a television or a near-eye display system.

### SUMMARY

This disclosure relates generally to micro-light emitting diode (micro-LED) devices. More specifically, and without limitation, techniques disclosed herein relate to core-shell nanowire micro-LEDs with improved performance and manufacturability for micro-displays. Various inventive embodiments are described herein, including devices, systems, methods, structures, materials, processes, and the like.

According to certain embodiments, a light source may include an array of core-shell nanowire micro-LEDs. Each core-shell nanowire micro-LED of the array of core-shell nanowire micro-LEDs may include a first semiconductor epitaxial layer including a nanowire core formed therein; a first dielectric material layer in physical contact with and surrounding sidewalls of a bottom portion of the nanowire core, or in physical contact with a bottom surface of the nanowire core; a second dielectric material layer in physical contact with a top surface of the nanowire core; active layers grown only on sidewalls of the nanowire core and configured to emit visible light; and a second semiconductor layer grown on the active layers, where the nanowire core and the second semiconductor layer may be oppositely doped.

In some embodiments of the light source, a pitch of the array of core-shell nanowire micro-LEDs is equal to or less than about 2 μm, and a width of the nanowire core is equal to or less than about 1 μm, such as equal to or less than about 0.5 μm. In some embodiments, the light source may also include a layer of a high-refractive index material on sidewalls of the second semiconductor layer, the high-refractive index material characterized by a refractive index greater than a refractive index of the second semiconductor layer. The doping density of the nanowire core may be less than about 2×10²⁰ cm⁻³. In some embodiments, the first dielectric material layer may include SiO₂ or SiN, while the second dielectric material layer may include SiN.

In some embodiments of the light source, the sidewalls of the nanowire core may be on m-planes or semipolar planes. A cross-section of the nanowire core may be characterized by a hexagonal shape or a circular shape. In some embodiments, a first group of core-shell nanowire micro-LEDs of the array of core-shell nanowire micro-LEDs may be configured to emit blue light, and a second group of core-shell nanowire micro-LEDs of the array of core-shell nanowire micro-LEDs may be configured to emit green light. In some embodiments, a third group of core-shell nanowire micro-LEDs of the array of core-shell nanowire micro-LEDs may be configured to emit red light. Nanowire cores of the array of core-shell nanowire micro-LEDs may be characterized by a same height. In some embodiments, a height of the active layers may be less than a half of a height of the nanowire core.

According to certain embodiments, a method of fabricating core-shell nanowire micro-LEDs may include growing a first semiconductor layer on a substrate; forming etch masks on the first semiconductor layer; etching the first semiconductor layer using the etch masks to form a plurality of nanowire cores under the etch masks; forming a dielectric material layer in regions between nanowire cores of the plurality of nanowire cores; growing, with the etch masks on top of the plurality of nanowire cores, active layers on sidewalls of the plurality of nanowire cores, the active layers configured to emit visible light; and growing, with the etch masks on top of the plurality of nanowire cores, a second semiconductor layer on surfaces of the active layers, where the first semiconductor layer and the second semiconductor layer may be doped oppositely, and may, in combination with the plurality of nanowire cores, form an array of core-shell nanowire micro-LEDs.

In some embodiments, the method may also include, before growing the active layers on the sidewalls of the plurality of nanowire cores, treating the sidewalls of the plurality of nanowire cores using KOH or tetramethyl ammonium hydroxide (TMAH). In some embodiments, the method may also include depositing a layer of a high-refractive index material on sidewalls of the second semiconductor layer, the high-refractive index material characterized by a refractive index greater than a refractive index of the second semiconductor layer. In some embodiments, growing the active layers on the sidewalls of the plurality of nanowire cores and growing the second semiconductor layer on the surfaces of the active layers may include: applying a first mask layer on a first set of nanowire cores of the plurality of nanowire cores; growing first active layers on sidewalls of a second set of nanowire cores of the plurality of nanowire cores, the first active layers configured to emit light in a first wavelength range; growing the second semiconductor layer on surfaces of the first active layers; removing the first mask layer; applying a second mask layer on surfaces of the second semiconductor layer grown on the surfaces of the first active layers; growing second active layers on sidewalls of the first set of nanowire cores of the plurality of nanowire cores, the second active layers configured to emit light in a second wavelength range; and growing the second semiconductor layer on surfaces of the second active layers.

In some embodiments, growing the first semiconductor layer may include epitaxial lateral overgrowth through a growth mask layer. In some embodiments, forming the dielectric material layer in the regions between the nanowire cores of the plurality of nanowire cores may include: conformally depositing a layer of a dielectric material on surfaces of the first semiconductor layer; spin-coating a photoresist layer on the layer of the dielectric material; ashing the photoresist layer to leave photoresist only in the regions between the nanowire cores of the plurality of nanowire cores; and etching the layer of the dielectric material using the photoresist in the regions between the nanowire cores of the plurality of nanowire cores as a mask layer. In some embodiments, forming the dielectric material layer in the regions between the nanowire cores of the plurality of nanowire cores may include depositing a layer of a dielectric material to fill the regions between the nanowire cores of the plurality of nanowire cores, and etching the layer of the dielectric material using the etch masks on top of the plurality of nanowire cores.

This summary is neither intended to identify key or essential features of the claimed subject matter, nor is it intended to be used in isolation to determine the scope of the claimed subject matter. The subject matter should be understood by reference to appropriate portions of the entire specification of this disclosure, any or all drawings, and each claim. The foregoing, together with other features and examples, will be described in more detail below in the following specification, claims, and accompanying drawings.

### BRIEF DESCRIPTION OF THE DRAWINGS

Illustrative embodiments are described in detail below with reference to the following figures.

FIG. 1 is a simplified block diagram of an example of an artificial reality system environment including a near-eye display according to certain embodiments.

FIG. 2 is a perspective view of an example of a near-eye display in the form of a head-mounted display (HMD) device for implementing some of the examples disclosed herein.

FIG. 3 is a perspective view of an example of a near-eye display in the form of a pair of glasses for implementing some of the examples disclosed herein.

FIG. 4 illustrates an example of an optical see-through augmented reality system including a waveguide display according to certain embodiments.

FIG. 5A illustrates an example of a near-eye display device including a waveguide display according to certain embodiments.

FIG. 5B illustrates an example of a near-eye display device including a waveguide display according to certain embodiments.

FIG. 6 illustrates an example of an image source assembly in an augmented reality system according to certain embodiments.

FIG. 7A illustrates an example of a light emitting diode (LED) having a vertical mesa structure according to certain embodiments.

FIG. 7B is a cross-sectional view of an example of an LED having a parabolic mesa structure according to certain embodiments.

FIGS. 8A-8D illustrate an example of a method of hybrid bonding for arrays of LEDs according to certain embodiments.

FIG. 9 illustrates an example of an LED array with secondary optical components fabricated thereon according to certain embodiments.

FIG. 10A illustrates an example of a method of die-to-wafer bonding for arrays of LEDs according to certain embodiments.

FIG. 10B illustrates an example of a method of wafer-to-wafer bonding for arrays of LEDs according to certain embodiments.

FIGS. 11A-11F illustrate an example of a method of fabricating a micro-LED device using alignment-free metal-to-metal bonding and post-bonding mesa formation.

FIGS. 12A-12E illustrate an example of a process of fabricating a micro-LED device according to certain embodiments.

FIG. 13A illustrates an example of an array of nanowire micro-LEDs.

FIG. 13B illustrates changes in the external quantum efficiencies of conventional micro-LEDs and core-shell nanowire micro-LEDs as the sizes of the micro-LEDs reduce.

FIGS. 14A-14C illustrate an example of a method of fabricating core-shell nanowire micro-LEDs.

FIG. 14D illustrates an example of a core-shell nanowire micro-LED with parasitic r-plane growth.

FIGS. 15A-15F illustrate an example of a method of fabricating core-shell nanowire micro-LEDs with improved performance according to certain embodiments.

FIGS. 16A-16F illustrate another example of a method of fabricating nanowire micro-LEDs with improved performance according to certain embodiments.

FIGS. 17A-17F illustrate yet another example of a method of fabricating nanowire micro-LEDs with improved performance according to certain embodiments.

FIGS. 18A-18F illustrate another example of a method of fabricating nanowire micro-LEDs with improved performance according to certain embodiments.

FIGS. 19A-19H illustrate an example of a method of fabricating multi-color nanowire micro-LEDs with improved performance according to certain embodiments.

FIG. 20A illustrates light emission by an example of a core-shell nanowire micro-LED according to certain embodiments.

FIG. 20B illustrates light emission by an example of a core-shell nanowire micro-LED including a waveguide structure according to certain embodiments.

FIG. 21 includes a flowchart illustrating an example of a process of fabricating core-shell nanowire micro-LEDs according to certain embodiments.

FIG. 22 is a simplified block diagram of an electronic system of an example of a near-eye display according to certain embodiments.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

### DETAILED DESCRIPTION

This disclosure relates generally to micro-light emitting diode (micro-LED) devices. More specifically, and without limitation, techniques disclosed herein relate to core-shell nanowire micro-LEDs with improved performance and manufacturability for micro-displays. Various inventive embodiments are described herein, including devices, systems, methods, structures, materials, processes, and the like.

Augmented reality (AR) and virtual reality (VR) applications may use near-eye displays that include tiny monochrome light emitters, such as mini- or micro-LEDs. In light emitting diodes (LEDs), photons may be generated through the recombination of electrons and holes within an active region (e.g., including one or more semiconductor layers that may form one or more quantum wells). The proportion of the carriers (e.g., electrons or holes) injected into the active region of an LED among the carriers that pass through the LED is referred to as the carrier injection efficiency. The ratio between the number of emitted photons and the number of carriers injected into the active region is referred to as the internal quantum efficiency (IQE) of the LED. Light emitted in the active region may be extracted from the LED at a certain light extraction efficiency (LEE). The ratio between the number of emitted photons extracted from the LED and the number of electrons passing through the LED is referred to as the external quantum efficiency (EQE) of the LED, which describes how efficiently the LED converts injected carriers into photons that are extracted from the LED. The EQE may be a product of the carrier injection efficiency, the IQE, and the LEE. For LEDs with reduced physical dimensions, such as micro-LEDs, the IQEs and EQEs may be very low. Improving the efficiencies of the micro-LEDs can be challenging.

The internal quantum efficiency of an LED depends on the relative rates of competitive radiative (light producing) recombination and non-radiative (lossy) recombination that occur in the active region of the LED. Non-radiative recombination processes in the active region include Shockley-Read-Hall (SRH) recombination at defect sites, and electron-electron-hole (eeh) and/or electron-hole-hole (ehh) Auger recombination. The Auger recombination is a non-radiative process involving three carriers, which affects all sizes of LEDs. At the mesa sidewalls, the defect density of the active region may be very high due to the abrupt ending of the lattice structure, chemical contamination, and/or structural damages (e.g., due to dry etch). For example, in plasma etching, high-energy ions (e.g., Ar⁺, Cl₂⁺, Cl⁺, or HF⁺) may be used to bombard the exposed surfaces of semiconductor layers. Due to the bombardment by high-energy particles, the surfaces created by the etching may be highly damaged, where the damages may include alterations to the crystal structure or other modifications to the surfaces. The damages may extend into the interior of the mesa structure, such as about 50 nm to about 500 nm below the new surfaces formed by the etching. Therefore, the active region in proximity to the sidewalls of a mesa structure may have a high density of defects, such as lattice dislocations, dangling bonds, pores, grain boundaries, vacancies, surface oxides, surfaces modifications by plasma atoms, interstitial defects, substitutional defects, inclusion of precipitates, and the like. The defects may introduce energy states having deep or shallow energy levels in the bandgap. Carriers may be trapped by these energy states until they recombine non-radiatively. Therefore, the active region in proximity to the mesa sidewalls may have a higher rate of SRH recombination, which may reduce the efficiency of the LED.

Due to the small size of the mesa structure of a micro-LED (e.g., with a width less than about 10 μm, less than about 5 μm, less than about 3 μm, or less than about 2 μm), a large proportion of the injected carriers may diffuse to regions near the mesa sidewalls and may be subjected to the higher SRH recombination rate. This may cause the efficiency of the LED to decrease (in particular, at low current injection), cause the peak efficiency of the LED to decrease, and/or cause the peak efficiency operating current to increase. Increasing the injected current may cause the efficiencies of the micro-LEDs to drop due to the higher eeh or ehh Auger recombination rate at a higher current density, and may also cause spectral shift of the emitted light. As the physical sizes of LEDs are further reduced, efficiency losses due to surface recombination near the etched sidewall facets that include surface imperfections may become much more significant. III-phosphide materials, such as AlGaInP, can have a high surface recombination velocity and minority carrier diffusion length. For example, carriers in AlGaInP can have high diffusivity (mobility), and AlGaInP may have an order of magnitude higher surface recombination velocity than III-nitride materials. Thus, the internal and external quantum efficiencies of AlGaInP-based red light-emitting LEDs may drop even more significantly as the device size reduces.

In addition, at the light-emitting surface of an LED, such as the interface between the LED and air, incident light with incident angles greater than a critical angle may be reflected back to the LED due to total internal reflection (TIR). Because of the geometry of the LED, some light reflected back to the LED may be trapped and eventually be absorbed by the LED. For example, some trapped light may be absorbed by the semiconductor materials to generate electron-hole pairs, which may recombine radiatively or non-radiatively. Some trapped light may be absorbed by metals (e.g., metal contacts or reflectors) at the bottom and/or sidewalls of the LED due to, for example, surface plasmon resonance that may be excited by p-polarized light at the interface between a metal layer and a dielectric layer (e.g., the passivation layer). Because of the high refractive indices of many III-V semiconductor materials (e.g., about 2.4 for GaN, and greater than about 3.0 for GaP, InP, GaInP, and AlGaInP), the critical angle for total internal reflection at the interface between the III-V semiconductor material and an adjacent lower refractive index material (e.g., air or a dielectric) may be small. As such, a large portion of the light emitted in the active region of a III-V material-based LED may be trapped in the LED due to TIR, and may eventually be absorbed by the LED. Therefore, the LEE of the micro-LED may be low.

Core-shell nanowire micro-LEDs with epitaxially grown active regions may have high IQEs because the active regions can have a large area (e.g., in a vertical plane), and the active regions are generally not etched and thus may have low defect densities and low non-radiative recombination rates. In addition, no sidewall passivation may be needed. There are no exposed mesa edges and thus there may not be associated reliability concerns. It is possible to make core-shell nanowire micro-LEDs with pitches less than about 1 μm (e.g., with width of nanowire about 0.5 μm). Multiple nanowire micro-LEDs may be grouped together to form a single pixel. Therefore, the pixel may still be functional even if one or more nanowire micro-LEDs in the group are not functional.

However, growing the cores (e.g., n-doped cores) of the nanowires through selective area growth (SAG) may need a higher doping density (e.g., >1×10²⁰/cm³) in order to grow the cores vertically. Due to the high doping density, the cores may have a high defect density, and thus the subsequently grown active layers may have a high defect density and a low quality. In addition, the heights of the vertically grown nanowire cores may vary significantly across a wafer. Furthermore, growing active layers on the cores grown by SAG may also grow parasitic active layers on the c-plane or r-plane, in addition to the m-plane active layers. The c-plane or r-plane active layers may emit light with wavelengths different from the wavelengths of the light emitted by m-plane active layers. Due to the simultaneous growth of active layers on the en-planes, c-plane, and r-planes, the window of the growth condition may be narrow, and thus the growth condition may need to be more precisely controlled. Moreover, the active layers grown at the bottom of the nanowire cores may have lower quality and thus lower quantum efficiency.

According to certain embodiments, the cores of nanowire micro-LEDs may be formed by etching an epitaxial layers using an etch mask, where the remaining etch mask may then be used as the growth mask on top of the nanowire cores during the growth of the active region, such that no parasitic c-plane or r-plane active layers may be grown on top of the nanowire cores. Since the nanowire cores may be formed by etching a uniform semiconductor layer that may be relatively low-doped, the heights of the nanowire cores may be more uniform and the quality of the nanowire cores may be better, compared with nanowire cores formed by SAG. Because the active layers may only be grown on the m-planes, the window of the growth condition can be wide. Core-shell nanowire micro-LEDs configured to emit light of different colors may be formed on a same wafer using techniques disclosed herein. Additional structures may be formed on the core-shell nanowire micro-LEDs to guide the light emitted in the active layers, such that light beams emitted from the core-shell nanowire micro-LEDs may be more directional and may be more efficiently coupled to, for example, a waveguide display.

The micro-LEDs described herein may be used in conjunction with various technologies, such as an artificial reality system. An artificial reality system, such as a head-mounted display (HMD) or heads-up display (HUD) system, generally includes a display configured to present artificial images that depict objects in a virtual environment. The display may present virtual objects or combine images of real objects with virtual objects, as in virtual reality (VR), augmented reality (AR), or mixed reality (MR) applications. For example, in an AR system, a user may view both displayed images of virtual objects (e.g., computer-generated images (CGIs)) and the surrounding environment by, for example, seeing through transparent display glasses or lenses (often referred to as optical see-through) or viewing displayed images of the surrounding environment captured by a camera (often referred to as video see-through). In some AR systems, the artificial images may be presented to users using an LED-based display subsystem.

In the following description, for the purposes of explanation, specific details are set forth in order to provide a thorough understanding of examples of the disclosure. However, it will be apparent that various examples may be practiced without these specific details. For example, devices, systems, structures, assemblies, methods, and other components may be shown as components in block diagram form in order not to obscure the examples in unnecessary detail. In other instances, well-known devices, processes, systems, structures, and techniques may be shown without necessary detail in order to avoid obscuring the examples. The figures and description are not intended to be restrictive. The terms and expressions that have been employed in this disclosure are used as terms of description and not of limitation, and there is no intention in the use of such terms and expressions of excluding any equivalents of the features shown and described or portions thereof. The word “example” is used herein to mean “serving as an example, instance, or illustration.” Any embodiment or design described herein as “example” is not necessarily to be construed as preferred or advantageous over other embodiments or designs.

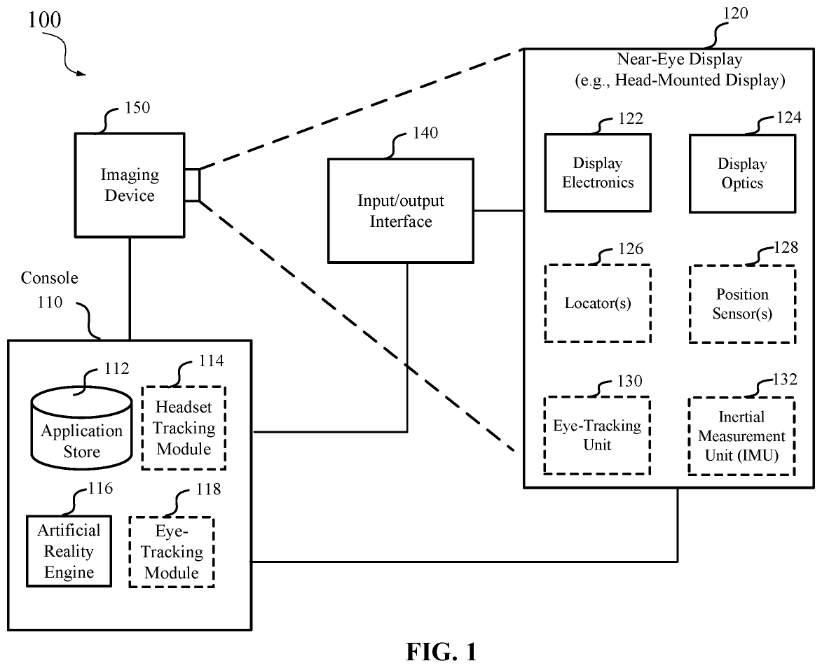

FIG. 1 is a simplified block diagram of an example of an artificial reality system environment 100 including a near-eye display 120 in accordance with certain embodiments. Artificial reality system environment 100 shown in FIG. 1 may include near-eye display 120, an optional external imaging device 150, and an optional input/output interface 140, each of which may be coupled to an optional console 110. While FIG. 1 shows an example of artificial reality system environment 100 including one near-eye display 120, one external imaging device 150, and one input/output interface 140, any number of these components may be included in artificial reality system environment 100, or any of the components may be omitted. For example, there may be multiple near-eye displays 120 monitored by one or more external imaging devices 150 in communication with console 110. In some configurations, artificial reality system environment 100 may not include external imaging device 150, optional input/output interface 140, and optional console 110. In alternative configurations, different or additional components may be included in artificial reality system environment 100.

Near-eye display 120 may be a head-mounted display that presents content to a user. Examples of content presented by near-eye display 120 include one or more of images, videos, audio, or any combination thereof. In some embodiments, audio may be presented via an external device (e.g., speakers and/or headphones) that receives audio information from near-eye display 120, console 110, or both, and presents audio data based on the audio information. Near-eye display 120 may include one or more rigid bodies, which may be rigidly or non-rigidly coupled to each other. A rigid coupling between rigid bodies may cause the coupled rigid bodies to act as a single rigid entity. A non-rigid coupling between rigid bodies may allow the rigid bodies to move relative to each other. In various embodiments, near-eye display 120 may be implemented in any suitable form-factor, including a pair of glasses. Some embodiments of near-eye display 120 are further described below with respect to FIGS. 2 and 3. Additionally, in various embodiments, the functionality described herein may be used in a headset that combines images of an environment external to near-eye display 120 and artificial reality content (e.g., computer-generated images). Therefore, near-eye display 120 may augment images of a physical, real-world environment external to near-eye display 120 with generated content (e.g., images, video, sound, etc.) to present an augmented reality to a user.

In various embodiments, near-eye display 120 may include one or more of display electronics 122, display optics 124, and an eye-tracking unit 130. In some embodiments, near-eye display 120 may also include one or more locators 126, one or more position sensors 128, and an inertial measurement unit (IMU) 132. Near-eye display 120 may omit any of eye-tracking unit 130, locators 126, position sensors 128, and IMU 132, or include additional elements in various embodiments. Additionally, in some embodiments, near-eye display 120 may include elements combining the function of various elements described in conjunction with FIG. 1.

Display electronics 122 may display or facilitate the display of images to the user according to data received from, for example, console 110. In various embodiments, display electronics 122 may include one or more display panels, such as a liquid crystal display (LCD), an organic light emitting diode (OLED) display, an inorganic light emitting diode (ILED) display, a micro light emitting diode (μLED) display, an active-matrix OLED display (AMOLED), a transparent OLED display (TOLED), or some other display. For example, in one implementation of near-eye display 120, display electronics 122 may include a front TOLED panel, a rear display panel, and an optical component (e.g., an attenuator, polarizer, or diffractive or spectral film) between the front and rear display panels. Display electronics 122 may include pixels to emit light of a predominant color such as red, green, blue, white, or yellow. In some implementations, display electronics 122 may display a three-dimensional (3D) image through stereoscopic effects produced by two-dimensional panels to create a subjective perception of image depth. For example, display electronics 122 may include a left display and a right display positioned in front of a user's left eye and right eye, respectively. The left and right displays may present copies of an image shifted horizontally relative to each other to create a stereoscopic effect (i.e., a perception of image depth by a user viewing the image).

In certain embodiments, display optics 124 may display image content optically (e.g., using optical waveguides and couplers) or magnify image light received from display electronics 122, correct optical errors associated with the image light, and present the corrected image light to a user of near-eye display 120. In various embodiments, display optics 124 may include one or more optical elements, such as, for example, a substrate, optical waveguides, an aperture, a Fresnel lens, a convex lens, a concave lens, a filter, input/output couplers, or any other suitable optical elements that may affect image light emitted from display electronics 122. Display optics 124 may include a combination of different optical elements as well as mechanical couplings to maintain relative spacing and orientation of the optical elements in the combination. One or more optical elements in display optics 124 may have an optical coating, such as an antireflective coating, a reflective coating, a filtering coating, or a combination of different optical coatings.

Locators 126 may be objects located in specific positions on near-eye display 120 relative to one another and relative to a reference point on near-eye display 120. In some implementations, console 110 may identify locators 126 in images captured by external imaging device 150 to determine the artificial reality headset's position, orientation, or both. A locator 126 may be an LED, a corner cube reflector, a reflective marker, a type of light source that contrasts with an environment in which near-eye display 120 operates, or any combination thereof. In embodiments where locators 126 are active components (e.g., LEDs or other types of light emitting devices).

External imaging device 150 may include one or more cameras, one or more video cameras, any other device capable of capturing images including one or more of locators 126, or any combination thereof. Additionally, external imaging device 150 may include one or more filters (e.g., to increase signal to noise ratio). External imaging device 150 may be configured to detect light emitted or reflected from locators 126 in a field of view of external imaging device 150. In embodiments where locators 126 include passive elements (e.g., retroreflectors), external imaging device 150 may include a light source that illuminates some or all of locators 126, which may retro-reflect the light to the light source in external imaging device 150. Slow calibration data may be communicated from external imaging device 150 to console 110, and external imaging device 150 may receive one or more calibration parameters from console 110 to adjust one or more imaging parameters (e.g., focal length, focus, frame rate, sensor temperature, shutter speed, aperture, etc.).

Position sensors 128 may generate one or more measurement signals in response to motion of near-eye display 120. Examples of position sensors 128 may include accelerometers, gyroscopes, magnetometers, other motion-detecting or error-correcting sensors, or any combination thereof. For example, in some embodiments, position sensors 128 may include multiple accelerometers to measure translational motion (e.g., forward/back, up/down, or left/right) and multiple gyroscopes to measure rotational motion (e.g., pitch, yaw, or roll). In some embodiments, various position sensors may be oriented orthogonally to each other.

IMU 132 may be an electronic device that generates fast calibration data based on measurement signals received from one or more of position sensors 128. Position sensors 128 may be located external to IMU 132, internal to IMU 132, or any combination thereof. Based on the one or more measurement signals from one or more position sensors 128, IMU 132 may generate fast calibration data indicating an estimated position of near-eye display 120 relative to an initial position of near-eye display 120.

Eye-tracking unit 130 may include one or more eye-tracking systems. Eye tracking may refer to determining an eye's position, including orientation and location of the eye, relative to near-eye display 120. An eye-tracking system may include an imaging system to image one or more eyes and may optionally include a light emitter, which may generate light that is directed to an eye such that light reflected by the eye may be captured by the imaging system. Near-eye display 120 may use the orientation of the eye to, e.g., determine an inter-pupillary distance (IPD) of the user, determine gaze direction, introduce depth cues (e.g., blur image outside of the user's main line of sight), collect heuristics on the user interaction in the VR media (e.g., time spent on any particular subject, object, or frame as a function of exposed stimuli), some other functions that are based in part on the orientation of at least one of the user's eyes, or any combination thereof.

Input/output interface 140 may be a device that allows a user to send action requests to console 110. An action request may be a request to perform a particular action. For example, an action request may be to start or to end an application or to perform a particular action within the application. Input/output interface 140 may include one or more input devices. Example input devices may include a keyboard, a mouse, a game controller, a glove, a button, a touch screen, or any other suitable device for receiving action requests and communicating the received action requests to console 110. An action request received by the input/output interface 140 may be communicated to console 110, which may perform an action corresponding to the requested action. In some embodiments, input/output interface 140 may provide haptic feedback to the user in accordance with instructions received from console 110. In some embodiments, external imaging device 150 may be used to track input/output interface 140, such as tracking the location or position of a controller (which may include, for example, an IR light source) or a hand of the user to determine the motion of the user. In some embodiments, near-eye display 120 may include one or more imaging devices to track input/output interface 140, such as tracking the location or position of a controller or a hand of the user to determine the motion of the user.

Console 110 may provide content to near-eye display 120 for presentation to the user in accordance with information received from one or more of external imaging device 150, near-eye display 120, and input/output interface 140. In the example shown in FIG. 1, console 110 may include an application store 112, a headset tracking module 114, an artificial reality engine 116, and an eye-tracking module 118. Some embodiments of console 110 may include different or additional modules than those described in conjunction with FIG. 1. Functions further described below may be distributed among components of console 110 in a different manner than is described here.

In some embodiments, console 110 may include a processor and a non-transitory computer-readable storage medium storing instructions executable by the processor. The processor may include multiple processing units executing instructions in parallel. The non-transitory computer-readable storage medium may be any memory, such as a hard disk drive, a removable memory, or a solid-state drive (e.g., flash memory or dynamic random access memory (DRAM)). In various embodiments, the modules of console 110 described in conjunction with FIG. 1 may be encoded as instructions in the non-transitory computer-readable storage medium that, when executed by the processor, cause the processor to perform the functions further described below.

Application store 112 may store one or more applications for execution by console 110. An application may include a group of instructions that, when executed by a processor, generates content for presentation to the user. Content generated by an application may be in response to inputs received from the user via movement of the user's eyes or inputs received from the input/output interface 140. Examples of the applications may include gaming applications, conferencing applications, video playback application, or other suitable applications.

Headset tracking module 114 may track movements of near-eye display 120 using slow calibration information from external imaging device 150. For example, headset tracking module 114 may determine positions of a reference point of near-eye display 120 using observed locators from the slow calibration information and a model of near-eye display 120. Headset tracking module 114 may also determine positions of a reference point of near-eye display 120 using position information from the fast calibration information. Additionally, in some embodiments, headset tracking module 114 may use portions of the fast calibration information, the slow calibration information, or any combination thereof, to predict a future location of near-eye display 120. Headset tracking module 114 may provide the estimated or predicted future position of near-eye display 120 to artificial reality engine 116.

Artificial reality engine 116 may execute applications within artificial reality system environment 100 and receive position information of near-eye display 120, acceleration information of near-eye display 120, velocity information of near-eye display 120, predicted future positions of near-eye display 120, or any combination thereof from headset tracking module 114. Artificial reality engine 116 may also receive estimated eye position and orientation information from eye-tracking module 118. Based on the received information, artificial reality engine 116 may determine content to provide to near-eye display 120 for presentation to the user.

Artificial reality engine 116 may perform an action within an application executing on console 110 in response to an action request received from input/output interface 140, and provide feedback to the user indicating that the action has been performed. The feedback may be visual or audible feedback via near-eye display 120 or haptic feedback via input/output interface 140.

Eye-tracking module 118 may receive eye-tracking data from eye-tracking unit 130 and determine the position of the user's eye based on the eye tracking data. The position of the eye may include an eye's orientation, location, or both relative to near-eye display 120 or any element thereof. Because the eye's axes of rotation change as a function of the eye's location in its socket, determining the eye's location in its socket may allow eye-tracking module 118 to determine the eye's orientation more accurately.

FIG. 2 is a perspective view of an example of a near-eye display in the form of an HMD device 200 for implementing some of the examples disclosed herein. HMD device 200 may be a part of, e.g., a VR system, an AR system, an MR system, or any combination thereof. HMD device 200 may include a body 220 and a head strap 230. FIG. 2 shows a bottom side 223, a front side 225, and a left side 227 of body 220 in the perspective view. Head strap 230 may have an adjustable or extendible length. There may be a sufficient space between body 220 and head strap 230 of HMD device 200 for allowing a user to mount HMD device 200 onto the user's head. In various embodiments, HMD device 200 may include additional, fewer, or different components. For example, in some embodiments, HMD device 200 may include eyeglass temples and temple tips as shown in, for example, FIG. 3 below, rather than head strap 230.

HMD device 200 may present to a user media including virtual and/or augmented views of a physical, real-world environment with computer-generated elements. Examples of the media presented by HMD device 200 may include images (e.g., two-dimensional (2D) or three-dimensional (3D) images), videos (e.g., 2D or 3D videos), audio, or any combination thereof. The images and videos may be presented to each eye of the user by one or more display assemblies (not shown in FIG. 2) enclosed in body 220 of HMD device 200. In various embodiments, the one or more display assemblies may include a single electronic display panel or multiple electronic display panels (e.g., one display panel for each eye of the user). Examples of the electronic display panel(s) may include, for example, an LCD, an OLED display, an ILED display, a OLED display, an AMOLED, a TOLED, some other display, or any combination thereof. HMD device 200 may include two eye box regions.

In some implementations, HMD device 200 may include various sensors (not shown), such as depth sensors, motion sensors, position sensors, and eye tracking sensors. Some of these sensors may use a structured light pattern for sensing. In some implementations, HMD device 200 may include an input/output interface for communicating with a console. In some implementations, HMD device 200 may include a virtual reality engine (not shown) that can execute applications within HMD device 200 and receive depth information, position information, acceleration information, velocity information, predicted future positions, or any combination thereof of HMD device 200 from the various sensors. In some implementations, the information received by the virtual reality engine may be used for producing a signal (e.g., display instructions) to the one or more display assemblies. In some implementations, HMD device 200 may include locators (not shown, such as locators 126) located in fixed positions on body 220 relative to one another and relative to a reference point. Each of the locators may emit light that is detectable by an external imaging device.

FIG. 3 is a perspective view of an example of a near-eye display 300 in the form of a pair of glasses for implementing some of the examples disclosed herein. Near-eye display 300 may be a specific implementation of near-eye display 120 of FIG. 1, and may be configured to operate as a virtual reality display, an augmented reality display, and/or a mixed reality display. Near-eye display 300 may include a frame 305 and a display 310. Display 310 may be configured to present content to a user. In some embodiments, display 310 may include display electronics and/or display optics. For example, as described above with respect to near-eye display 120 of FIG. 1, display 310 may include an LCD display panel, an LED display panel, or an optical display panel (e.g., a waveguide display assembly).

Near-eye display 300 may further include various sensors 350a, 350b, 350c, 350d, and 350e on or within frame 305. In some embodiments, sensors 350a-350e may include one or more depth sensors, motion sensors, position sensors, inertial sensors, or ambient light sensors. In some embodiments, sensors 350a-350e may include one or more image sensors configured to generate image data representing different fields of views in different directions. In some embodiments, sensors 350a-350e may be used as input devices to control or influence the displayed content of near-eye display 300, and/or to provide an interactive VR/AR/MR experience to a user of near-eye display 300. In some embodiments, sensors 350a-350e may also be used for stereoscopic imaging.

In some embodiments, near-eye display 300 may further include one or more illuminators 330 to project light into the physical environment. The projected light may be associated with different frequency bands (e.g., visible light, infra-red light, ultra-violet light, etc.), and may serve various purposes. For example, illuminator(s) 330 may project light in a dark environment (or in an environment with low intensity of infra-red light, ultra-violet light, etc.) to assist sensors 350a-350e in capturing images of different objects within the dark environment. In some embodiments, illuminator(s) 330 may be used to project certain light patterns onto the objects within the environment. In some embodiments, illuminator(s) 330 may be used as locators, such as locators 126 described above with respect to FIG. 1.

In some embodiments, near-eye display 300 may also include a high-resolution camera 340. Camera 340 may capture images of the physical environment in the field of view. The captured images may be processed, for example, by a virtual reality engine (e.g., artificial reality engine 116 of FIG. 1) to add virtual objects to the captured images or modify physical objects in the captured images, and the processed images may be displayed to the user by display 310 for AR or MR applications.

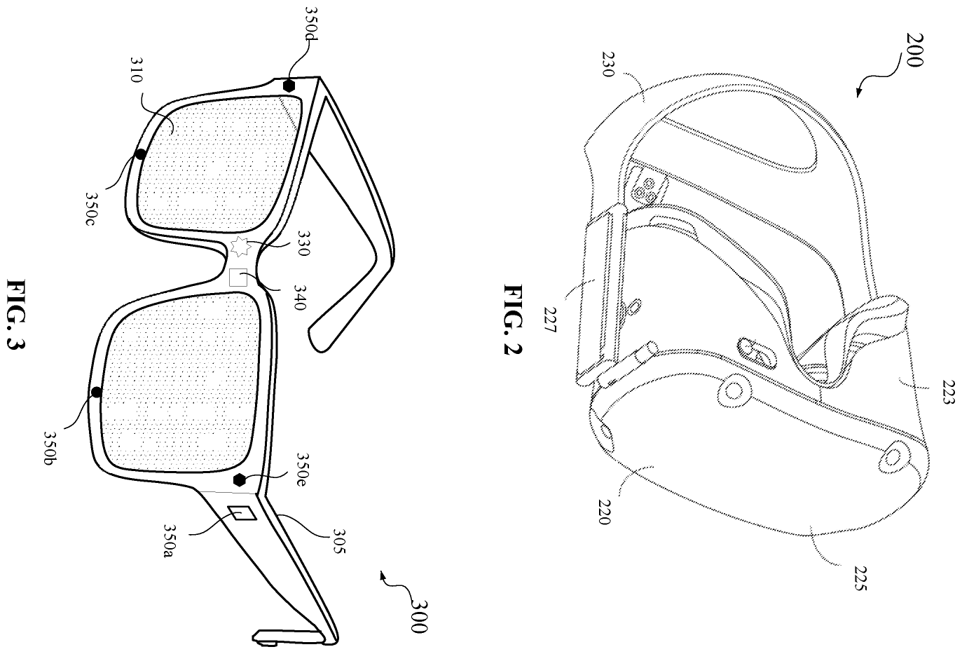

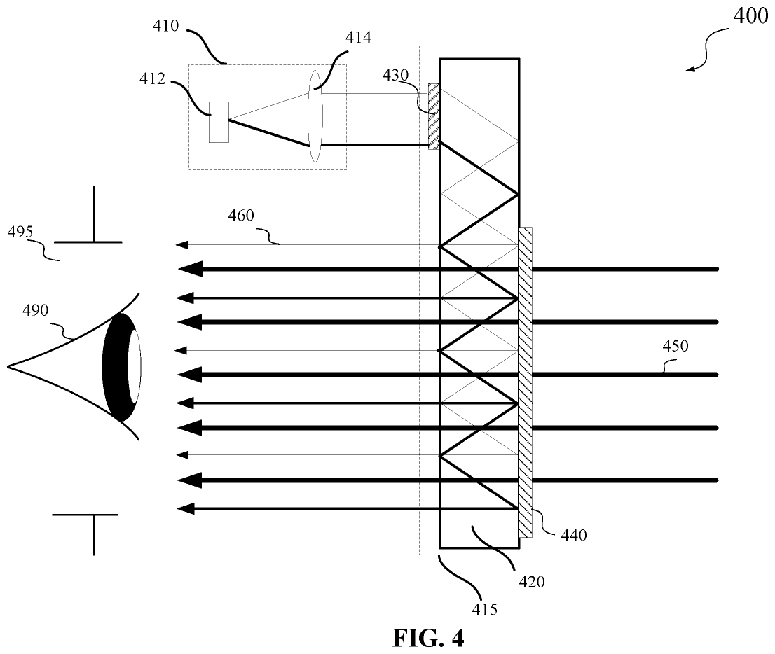

FIG. 4 illustrates an example of an optical see-through augmented reality system 400 including a waveguide display according to certain embodiments. Augmented reality system 400 may include a projector 410 and a combiner 415. Projector 410 may include a light source or image source 412 and projector optics 414. In some embodiments, light source or image source 412 may include one or more micro-LED devices described above. In some embodiments, image source 412 may include a plurality of pixels that displays virtual objects, such as an LCD display panel or an LED display panel. In some embodiments, image source 412 may include a light source that generates coherent or partially coherent light. For example, image source 412 may include a laser diode, a vertical cavity surface emitting laser, an LED, and/or a micro-LED described above. In some embodiments, image source 412 may include a plurality of light sources (e.g., an array of micro-LEDs described above), each emitting a monochromatic image light corresponding to a primary color (e.g., red, green, or blue). In some embodiments, image source 412 may include three two-dimensional arrays of micro-LEDs, where each two-dimensional array of micro-LEDs may include micro-LEDs configured to emit light of a primary color (e.g., red, green, or blue). In some embodiments, image source 412 may include an optical pattern generator, such as a spatial light modulator. Projector optics 414 may include one or more optical components that can condition the light from image source 412, such as expanding, collimating, scanning, or projecting light from image source 412 to combiner 415. The one or more optical components may include, for example, one or more lenses, liquid lenses, mirrors, apertures, and/or gratings. For example, in some embodiments, image source 412 may include one or more one-dimensional arrays or elongated two-dimensional arrays of micro-LEDs, and projector optics 414 may include one or more one-dimensional scanners (e.g., micro-mirrors or prisms) configured to scan the one-dimensional arrays or elongated two-dimensional arrays of micro-LEDs to generate image frames. In some embodiments, projector optics 414 may include a liquid lens (e.g., a liquid crystal lens) with a plurality of electrodes that allows scanning of the light from image source 412.

Combiner 415 may include an input coupler 430 for coupling light from projector 410 into a substrate 420 of combiner 415. Combiner 415 may transmit at least 50% of light in a first wavelength range and reflect at least 25% of light in a second wavelength range. For example, the first wavelength range may be visible light from about 400 nm to about 650 nm, and the second wavelength range may be in the infrared band, for example, from about 800 nm to about 1000 nm. Input coupler 430 may include a volume holographic grating, a diffractive optical element (DOE) (e.g., a surface-relief grating), a slanted surface of substrate 420, or a refractive coupler (e.g., a wedge or a prism). For example, input coupler 430 may include a reflective volume Bragg grating or a transmissive volume Bragg grating. Input coupler 430 may have a coupling efficiency of greater than 30%, 50%, 75%, 90%, or higher for visible light. Light coupled into substrate 420 may propagate within substrate 420 through, for example, total internal reflection (TIR). Substrate 420 may be in the form of a lens of a pair of eyeglasses. Substrate 420 may have a flat or a curved surface, and may include one or more types of dielectric materials, such as glass, quartz, plastic, polymer, poly(methyl methacrylate) (PMMA), crystal, or ceramic. A thickness of the substrate may range from, for example, less than about 1 mm to about 10 mm or more. Substrate 420 may be transparent to visible light.

Substrate 420 may include or may be coupled to a plurality of output couplers 440, each configured to extract at least a portion of the light guided by and propagating within substrate 420 from substrate 420, and direct extracted light 460 to an eyebox 495 where an eye 490 of the user of augmented reality system 400 may be located when augmented reality system 400 is in use. The plurality of output couplers 440 may replicate the exit pupil to increase the size of eyebox 495 such that the displayed image is visible in a larger area. As input coupler 430, output couplers 440 may include grating couplers (e.g., volume holographic gratings or surface-relief gratings), other diffraction optical elements (DOEs), prisms, etc. For example, output couplers 440 may include reflective volume Bragg gratings or transmissive volume Bragg gratings. Output couplers 440 may have different coupling (e.g., diffraction) efficiencies at different locations. Substrate 420 may also allow light 450 from the environment in front of combiner 415 to pass through with little or no loss. Output couplers 440 may also allow light 450 to pass through with little loss. For example, in some implementations, output couplers 440 may have a very low diffraction efficiency for light 450 such that light 450 may be refracted or otherwise pass through output couplers 440 with little loss, and thus may have a higher intensity than extracted light 460. In some implementations, output couplers 440 may have a high diffraction efficiency for light 450 and may diffract light 450 in certain desired directions (i.e., diffraction angles) with little loss. As a result, the user may be able to view combined images of the environment in front of combiner 415 and images of virtual objects projected by projector 410.

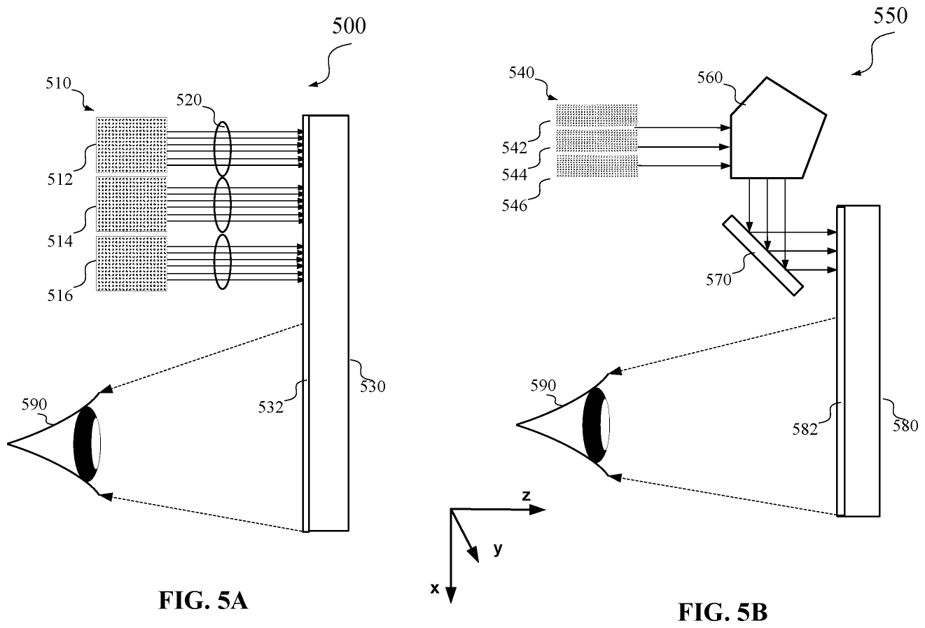

FIG. 5A illustrates an example of a near-eye display (NED) device 500 including a waveguide display 530 according to certain embodiments. NED device 500 may be an example of near-eye display 120, augmented reality system 400, or another type of display device. NED device 500 may include a light source 510, projection optics 520, and waveguide display 530. Light source 510 may include multiple panels of light emitters for different colors, such as a panel of red light emitters 512, a panel of green light emitters 514, and a panel of blue light emitters 516. The red light emitters 512 are organized into an array; the green light emitters 514 are organized into an array; and the blue light emitters 516 are organized into an array. The dimensions and pitches of light emitters in light source 510 may be small. For example, each light emitter may have a diameter less than 2 μm (e.g., about 1.2 μm) and the pitch may be less than 2 μm (e.g., about 1.5 μm). As such, the number of light emitters in each red light emitters 512, green light emitters 514, and blue light emitters 516 can be equal to or greater than the number of pixels in a display image, such as 960×720, 1280×720, 1440×1080, 1920×1080, 2160×1080, or 2560×1080 pixels. Thus, a display image may be generated simultaneously by light source 510. A scanning element may not be used in NED device 500.

Before reaching waveguide display 530, the light emitted by light source 510 may be conditioned by projection optics 520, which may include a lens array. Projection optics 520 may collimate or focus the light emitted by light source 510 to waveguide display 530, which may include a coupler 532 for coupling the light emitted by light source 510 into waveguide display 530. The light coupled into waveguide display 530 may propagate within waveguide display 530 through, for example, total internal reflection as described above with respect to FIG. 4. Coupler 532 may also couple portions of the light propagating within waveguide display 530 out of waveguide display 530 and towards user's eye 590.

FIG. 5B illustrates an example of a near-eye display (NED) device 550 including a waveguide display 580 according to certain embodiments. In some embodiments, NED device 550 may use a scanning mirror 570 to project light from a light source 540 to an image field where a user's eye 590 may be located. NED device 550 may be an example of near-eye display 120, augmented reality system 400, or another type of display device. Light source 540 may include one or more rows or one or more columns of light emitters of different colors, such as multiple rows of red light emitters 542, multiple rows of green light emitters 544, and multiple rows of blue light emitters 546. For example, red light emitters 542, green light emitters 544, and blue light emitters 546 may each include N rows, each row including, for example, 2560 light emitters (pixels). The red light emitters 542 are organized into an array; the green light emitters 544 are organized into an array; and the blue light emitters 546 are organized into an array. In some embodiments, light source 540 may include a single line of light emitters for each color. In some embodiments, light source 540 may include multiple columns of light emitters for each of red, green, and blue colors, where each column may include, for example, 1080 light emitters. In some embodiments, the dimensions and/or pitches of the light emitters in light source 540 may be relatively large (e.g., about 3-5 μm) and thus light source 540 may not include sufficient light emitters for simultaneously generating a full display image. For example, the number of light emitters for a single color may be fewer than the number of pixels (e.g., 2560×1080 pixels) in a display image. The light emitted by light source 540 may be a set of collimated or diverging beams of light.

Before reaching scanning mirror 570, the light emitted by light source 540 may be conditioned by various optical devices, such as collimating lenses or a freeform optical element 560. Freeform optical element 560 may include, for example, a multi-facet prism or another light folding element that may direct the light emitted by light source 540 towards scanning mirror 570, such as changing the propagation direction of the light emitted by light source 540 by, for example, about 90° or larger. In some embodiments, freeform optical element 560 may be rotatable to scan the light. Scanning mirror 570 and/or freeform optical element 560 may reflect and project the light emitted by light source 540 to waveguide display 580, which may include a coupler 582 for coupling the light emitted by light source 540 into waveguide display 580. The light coupled into waveguide display 580 may propagate within waveguide display 580 through, for example, total internal reflection as described above with respect to FIG. 4. Coupler 582 may also couple portions of the light propagating within waveguide display 580 out of waveguide display 580 and towards user's eye 590.

Scanning mirror 570 may include a microelectromechanical system (MEMS) mirror or any other suitable mirrors. Scanning mirror 570 may rotate to scan in one or two dimensions. As scanning mirror 570 rotates, the light emitted by light source 540 may be directed to a different area of waveguide display 580 such that a full display image may be projected onto waveguide display 580 and directed to user's eye 590 by waveguide display 580 in each scanning cycle. For example, in embodiments where light source 540 includes light emitters for all pixels in one or more rows or columns, scanning mirror 570 may be rotated in the column or row direction (e.g., x or y direction) to scan an image. In embodiments where light source 540 includes light emitters for some but not all pixels in one or more rows or columns, scanning mirror 570 may be rotated in both the row and column directions (e.g., both x and y directions) to project a display image (e.g., using a raster-type scanning pattern).

NED device 550 may operate in predefined display periods. A display period (e.g., display cycle) may refer to a duration of time in which a full image is scanned or projected. For example, a display period may be a reciprocal of the desired frame rate. In NED device 550 that includes scanning mirror 570, the display period may also be referred to as a scanning period or scanning cycle. The light generation by light source 540 may be synchronized with the rotation of scanning mirror 570. For example, each scanning cycle may include multiple scanning steps, where light source 540 may generate a different light pattern in each respective scanning step.

In each scanning cycle, as scanning mirror 570 rotates, a display image may be projected onto waveguide display 580 and user's eye 590. The actual color value and light intensity (e.g., brightness) of a given pixel location of the display image may be an average of the light beams of the three colors (e.g., red, green, and blue) illuminating the pixel location during the scanning period. After completing a scanning period, scanning mirror 570 may revert back to the initial position to project light for the first few rows of the next display image or may rotate in a reverse direction or scan pattern to project light for the next display image, where a new set of driving signals may be fed to light source 540. The same process may be repeated as scanning mirror 570 rotates in each scanning cycle. As such, different images may be projected to user's eye 590 in different scanning cycles.

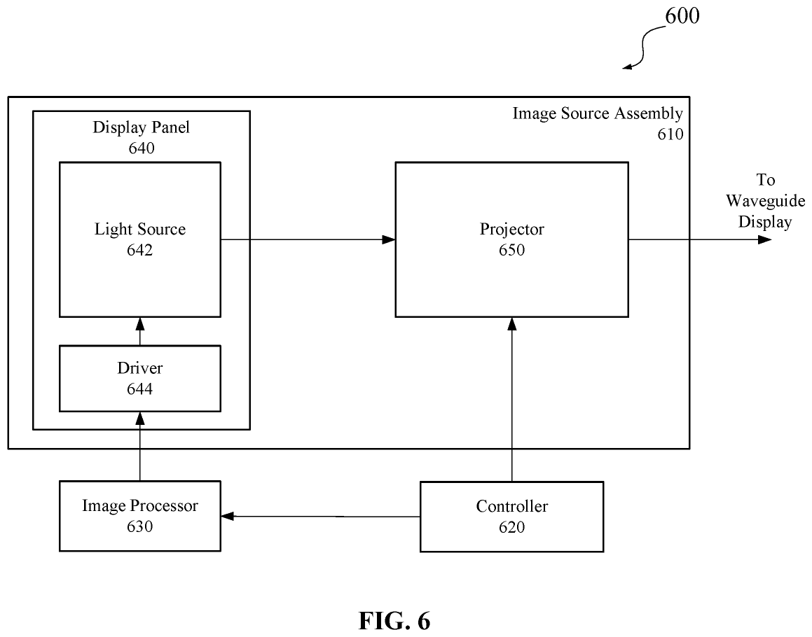

FIG. 6 illustrates an example of an image source assembly 610 in a near-eye display system 600 according to certain embodiments. Image source assembly 610 may include, for example, a display panel 640 that may generate display images to be projected to the user's eyes, and a projector 650 that may project the display images generated by display panel 640 to a waveguide display as described above with respect to FIGS. 4-5B. Display panel 640 may include a light source 642 and a drive circuit 644 for light source 642. Light source 642 may include, for example, light source 510 or 540. Projector 650 may include, for example, freeform optical element 560, scanning mirror 570, and/or projection optics 520 described above. Near-eye display system 600 may also include a controller 620 that synchronously controls light source 642 and projector 650 (e.g., scanning mirror 570). Image source assembly 610 may generate and output an image light to a waveguide display (not shown in FIG. 6), such as waveguide display 530 or 580. As described above, the waveguide display may receive the image light at one or more input-coupling elements, and guide the received image light to one or more output-coupling elements. The input and output coupling elements may include, for example, a diffraction grating, a holographic grating, a prism, or any combination thereof. The input-coupling element may be chosen such that total internal reflection occurs with the waveguide display. The output-coupling element may couple portions of the total internally reflected image light out of the waveguide display.

As described above, light source 642 may include a plurality of light emitters arranged in an array or a matrix. Each light emitter may emit monochromatic light, such as red light, blue light, green light, infra-red light, and the like. While RGB colors are often discussed in this disclosure, embodiments described herein are not limited to using red, green, and blue as primary colors. Other colors can also be used as the primary colors of near-eye display system 600. In some embodiments, a display panel in accordance with an embodiment may use more than three primary colors. Each pixel in light source 642 may include three subpixels that include a red micro-LED, a green micro-LED, and a blue micro-LED. A semiconductor LED generally includes an active light emitting layer within multiple layers of semiconductor materials. The multiple layers of semiconductor materials may include different compound materials or a same base material with different dopants and/or different doping densities. For example, the multiple layers of semiconductor materials may include an n-type material layer, an active region that may include hetero-structures (e.g., one or more quantum wells), and a p-type material layer. The multiple layers of semiconductor materials may be grown on a surface of a substrate having a certain orientation. In some embodiments, to increase light extraction efficiency, a mesa that includes at least some of the layers of semiconductor materials may be formed.

Controller 620 may control the image rendering operations of image source assembly 610, such as the operations of light source 642 and/or projector 650. For example, controller 620 may determine instructions for image source assembly 610 to render one or more display images.

The instructions may include display instructions and scanning instructions. In some embodiments, the display instructions may include an image file (e.g., a bitmap file). The display instructions may be received from, for example, a console, such as console 110 described above with respect to FIG. 1. The scanning instructions may be used by image source assembly 610 to generate image light. The scanning instructions may specify, for example, a type of a source of image light (e.g., monochromatic or polychromatic), a scanning rate, an orientation of a scanning apparatus, one or more illumination parameters, or any combination thereof. Controller 620 may include a combination of hardware, software, and/or firmware not shown here so as not to obscure other aspects of the present disclosure.

In some embodiments, controller 620 may be a graphics processing unit (GPU) of a display device. In other embodiments, controller 620 may be other kinds of processors. The operations performed by controller 620 may include taking content for display and dividing the content into discrete sections. Controller 620 may provide to light source 642 scanning instructions that include an address corresponding to an individual source element of light source 642 and/or an electrical bias applied to the individual source element. Controller 620 may instruct light source 642 to sequentially present the discrete sections using light emitters corresponding to one or more rows of pixels in an image ultimately displayed to the user. Controller 620 may also instruct projector 650 to perform different adjustments of the light. For example, controller 620 may control projector 650 to scan the discrete sections to different areas of a coupling element of the waveguide display (e.g., waveguide display 580) as described above with respect to FIG. 5B. As such, at the exit pupil of the waveguide display, each discrete portion is presented in a different respective location. While each discrete section is presented at a different respective time, the presentation and scanning of the discrete sections occur fast enough such that a user's eye may integrate the different sections into a single image or series of images.

Image processor 630 may be a general-purpose processor and/or one or more application-specific circuits that are dedicated to performing the features described herein. In one embodiment, a general-purpose processor may be coupled to a memory to execute software instructions that cause the processor to perform certain processes described herein. In another embodiment, image processor 630 may be one or more circuits that are dedicated to performing certain features. While image processor 630 in FIG. 6 is shown as a stand-alone unit that is separate from controller 620 and drive circuit 644, image processor 630 may be a sub-unit of controller 620 or drive circuit 644 in other embodiments. In other words, in those embodiments, controller 620 or drive circuit 644 may perform various image processing functions of image processor 630. Image processor 630 may also be referred to as an image processing circuit.

In the example shown in FIG. 6, light source 642 may be driven by drive circuit 644, based on data or instructions (e.g., display and scanning instructions) sent from controller 620 or image processor 630. In one embodiment, drive circuit 644 may include a circuit panel that connects to and mechanically holds various light emitters of light source 642. Light source 642 may emit light in accordance with one or more illumination parameters that are set by the controller 620 and potentially adjusted by image processor 630 and drive circuit 644. An illumination parameter may be used by light source 642 to generate light. An illumination parameter may include, for example, source wavelength, pulse rate, pulse amplitude, beam type (continuous or pulsed), other parameter(s) that may affect the emitted light, or any combination thereof. In some embodiments, the source light generated by light source 642 may include multiple beams of red light, green light, and blue light, or any combination thereof.

Projector 650 may perform a set of optical functions, such as focusing, combining, conditioning, or scanning the image light generated by light source 642. In some embodiments, projector 650 may include a combining assembly, a light conditioning assembly, or a scanning mirror assembly. Projector 650 may include one or more optical components that optically adjust and potentially re-direct the light from light source 642. One example of the adjustment of light may include conditioning the light, such as expanding, collimating, correcting for one or more optical errors (e.g., field curvature, chromatic aberration, etc.), some other adjustments of the light, or any combination thereof. The optical components of projector 650 may include, for example, lenses, mirrors, apertures, gratings, or any combination thereof.

Projector 650 may redirect image light via its one or more reflective and/or refractive portions so that the image light is projected at certain orientations toward the waveguide display. The location where the image light is redirected toward the waveguide display may depend on specific orientations of the one or more reflective and/or refractive portions. In some embodiments, projector 650 includes a single scanning mirror that scans in at least two dimensions. In other embodiments, projector 650 may include a plurality of scanning mirrors that each scan in directions orthogonal to each other. Projector 650 may perform a raster scan (horizontally or vertically), a bi-resonant scan, or any combination thereof In some embodiments, projector 650 may perform a controlled vibration along the horizontal and/or vertical directions with a specific frequency of oscillation to scan along two dimensions and generate a two-dimensional projected image of the media presented to user's eyes. In other embodiments, projector 650 may include a lens or prism that may serve similar or the same function as one or more scanning mirrors. In some embodiments, image source assembly 610 may not include a projector, where the light emitted by light source 642 may be directly incident on the waveguide display.

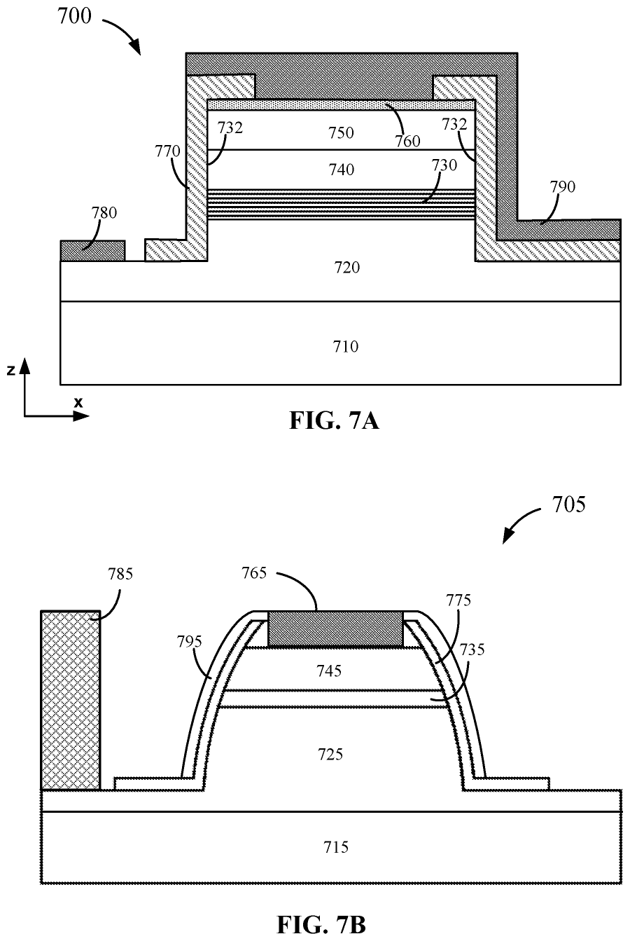

FIG. 7A illustrates an example of an LED 700 having a vertical mesa structure. LED 700 may be a light emitter in light source 510, 540, or 642. LED 700 may be a micro-LED made of inorganic materials, such as multiple layers of semiconductor materials. The layered semiconductor light emitting device may include multiple layers of III-V semiconductor materials. A III-V semiconductor material may include one or more Group III elements, such as aluminum (Al), gallium (Ga), or indium (In), in combination with a Group V element, such as nitrogen (N), phosphorus (P), arsenic (As), or antimony (Sb). When the Group V element of the III-V semiconductor material includes nitrogen, the III-V semiconductor material is referred to as a III-nitride material. The layered semiconductor light emitting device may be manufactured by growing multiple epitaxial layers on a substrate using techniques such as vapor-phase epitaxy (VPE), liquid-phase epitaxy (LPE), molecular beam epitaxy (MBE), or metalorganic chemical vapor deposition (MOCVD). For example, the layers of the semiconductor materials may be grown layer-by-layer on a substrate with a certain crystal lattice orientation (e.g., polar, nonpolar, or semi-polar orientation), such as a GaN, GaAs, or GaP substrate, or a substrate including, but not limited to, sapphire, silicon carbide, silicon, zinc oxide, boron nitride, lithium aluminate, lithium niobate, germanium, aluminum nitride, lithium gallate, partially substituted spinels, or quaternary tetragonal oxides sharing the beta-LiAlO₂ structure, where the substrate may be cut in a specific direction to expose a specific plane as the growth surface.

In the example shown in FIG. 7A, LED 700 may include a substrate 710, which may include, for example, a sapphire substrate or a GaN substrate. A semiconductor layer 720 may be grown on substrate 710. Semiconductor layer 720 may include a III-V material, such as GaN, and may be p-doped (e.g., with Mg, Ca, Zn, or Be) or n-doped (e.g., with Si or Ge). One or more active layers 730 may be grown on semiconductor layer 720 to form an active region. Active layer 730 may include III-V materials, such as one or more InGaN layers, one or more AlInGaP layers, and/or one or more GaN layers, which may form one or more heterostructures, such as one or more quantum wells or MQWs. A semiconductor layer 740 may be grown on active layer 730. Semiconductor layer 740 may include a III-V material, such as GaN, and may be p-doped (e.g., with Mg, Ca, Zn, or Be) or n-doped (e.g., with Si or Ge). One of semiconductor layer 720 and semiconductor layer 740 may be a p-type layer and the other one may be an n-type layer. Semiconductor layer 720 and semiconductor layer 740 sandwich active layer 730 to form the light emitting region. For example, LED 700 may include a layer of InGaN situated between a layer of p-type GaN doped with magnesium and a layer of n-type GaN doped with silicon or oxygen. In some embodiments, LED 700 may include a layer of AlInGaP situated between a layer of p-type AlInGaP doped with zinc or magnesium and a layer of n-type AlInGaP doped with selenium, silicon, or tellurium.

In some embodiments, an electron-blocking layer (EBL) (not shown in FIG. 7A) may be grown to form a layer between active layer 730 and at least one of semiconductor layer 720 or semiconductor layer 740. The EBL may reduce the electron leakage current and improve the efficiency of the LED. In some embodiments, a heavily-doped semiconductor layer 750, such as a P⁺ or P⁺⁺ semiconductor layer, may be formed on semiconductor layer 740 and act as a contact layer for forming an ohmic contact and reducing the contact impedance of the device. In some embodiments, a conductive layer 760 may be formed on heavily-doped semiconductor layer 750. Conductive layer 760 may include, for example, an indium tin oxide (ITO) or Al/Ni/Au film. In one example, conductive layer 760 may include a transparent ITO layer.

To make contact with semiconductor layer 720 (e.g., an n-GaN layer) and to more efficiently extract light emitted by active layer 730 from LED 700, the semiconductor material layers (including heavily-doped semiconductor layer 750, semiconductor layer 740, active layer 730, and semiconductor layer 720) may be etched to expose semiconductor layer 720 and to form a mesa structure that includes layers 720-760. The mesa structure may confine the carriers within the device. Etching the mesa structure may lead to the formation of mesa sidewalls 732 that may be orthogonal to the growth planes. A passivation layer 770 may be formed on mesa sidewalls 732 of the mesa structure. Passivation layer 770 may include an oxide layer, such as a SiO2 layer, and may act as a reflector to reflect emitted light out of LED 700. A contact layer 780, which may include a metal layer, such as Al, Au, Ni, Ti, or any combination thereof, may be formed on semiconductor layer 720 and may act as an electrode of LED 700. In addition, another contact layer 790, such as an Al/Ni/Au metal layer, may be formed on conductive layer 760 and may act as another electrode of LED 700.

When a voltage signal is applied to contact layers 780 and 790, electrons and holes may recombine in active layer 730, where the recombination of electrons and holes may cause photon emission. The wavelength and energy of the emitted photons may depend on the energy bandgap between the valence band and the conduction band in active layer 730. For example, InGaN active layers may emit green or blue light, AlGaN active layers may emit blue to ultraviolet light, while AlInGaP active layers may emit red, orange, yellow, or green light. The emitted photons may be reflected by passivation layer 770 and may exit LED 700 from the top (e.g., conductive layer 760 and contact layer 790) or bottom (e.g., substrate 710).

In some embodiments, LED 700 may include one or more other components, such as a lens, on the light emission surface, such as substrate 710, to focus or collimate the emitted light or couple the emitted light into a waveguide. In some embodiments, an LED may include a mesa of another shape, such as planar, conical, semi-parabolic, or parabolic, and a base area of the mesa may be circular, rectangular, hexagonal, or triangular. For example, the LED may include a mesa of a curved shape (e.g., paraboloid shape) and/or a non-curved shape (e.g., conic shape). The mesa may be truncated or non-truncated.

FIG. 7B is a cross-sectional view of an example of an LED 705 having a parabolic mesa structure. Similar to LED 700, LED 705 may include multiple layers of semiconductor materials, such as multiple layers of III-V semiconductor materials. The semiconductor material layers may be epitaxially grown on a substrate 715, such as a GaN substrate or a sapphire substrate. For example, a semiconductor layer 725 may be grown on substrate 715. Semiconductor layer 725 may include a III-V material, such as GaN, and may be p-doped (e.g., with Mg, Ca, Zn, or Be) or n-doped (e.g., with Si or Ge). One or more active layer 735 may be grown on semiconductor layer 725. Active layer 735 may include III-V materials, such as one or more InGaN layers, one or more AlInGaP layers, and/or one or more GaN layers, which may form one or more heterostructures, such as one or more quantum wells. A semiconductor layer 745 may be grown on active layer 735. Semiconductor layer 745 may include a III-V material, such as GaN, and may be p-doped (e.g., with Mg, Ca, Zn, or Be) or n-doped (e.g., with Si or Ge). One of semiconductor layer 725 and semiconductor layer 745 may be a p-type layer and the other one may be an n-type layer.

To make contact with semiconductor layer 725 (e.g., an n-type GaN layer) and to more efficiently extract light emitted by active layer 735 from LED 705, the semiconductor layers may be etched to expose semiconductor layer 725 and to form a mesa structure that includes layers 725-745. The mesa structure may confine carriers within the injection area of the device. Etching the mesa structure may lead to the formation of mesa side walls (also referred to herein as facets) that may be non-parallel with, or in some cases, orthogonal, to the growth planes associated with crystalline growth of layers 725-745.

As shown in FIG. 7B, LED 705 may have a mesa structure that includes a flat top. A dielectric layer 775 (e.g., SiO₂ or SiN) may be formed on the facets of the mesa structure. In some embodiments, dielectric layer 775 may include multiple layers of dielectric materials. In some embodiments, a metal layer 795 may be formed on dielectric layer 775. Metal layer 795 may include one or more metal or metal alloy materials, such as aluminum (Al), silver (Ag), gold (Au), platinum (Pt), titanium (Ti), copper (Cu), or any combination thereof. Dielectric layer 775 and metal layer 795 may form a mesa reflector that can reflect light emitted by active layer 735 toward substrate 715. In some embodiments, the mesa reflector may be parabolic-shaped to act as a parabolic reflector that may at least partially collimate the emitted light.

Electrical contact 765 and electrical contact 785 may be formed on semiconductor layer 745 and semiconductor layer 725, respectively, to act as electrodes. Electrical contact 765 and electrical contact 785 may each include a conductive material, such as Al, Au, Pt, Ag, Ni, Ti, Cu, or any combination thereof (e.g., Ag/Pt/Au or Al/Ni/Au), and may act as the electrodes of LED 705. In the example shown in FIG. 7B, electrical contact 785 may be an n-contact, and electrical contact 765 may be a p-contact. Electrical contact 765 and semiconductor layer 745 (e.g., a p-type semiconductor layer) may form a back reflector for reflecting light emitted by active layer 735 back toward substrate 715. In some embodiments, electrical contact 765 and metal layer 795 include same material(s) and can be formed using the same processes. In some embodiments, an additional conductive layer (not shown) may be included as an intermediate conductive layer between the electrical contacts 765 and 785 and the semiconductor layers.

When a voltage signal is applied across electrical contacts 765 and 785, electrons and holes may recombine in active layer 735. The recombination of electrons and holes may cause photon emission, thus producing light. The wavelength and energy of the emitted photons may depend on the energy bandgap between the valence band and the conduction band in active layer 735. For example, InGaN active layers may emit green or blue light, while AlInGaP active layers may emit red, orange, yellow, or green light. The emitted photons may propagate in many different directions, and may be reflected by the mesa reflector and/or the back reflector and may exit LED 705, for example, from the bottom side (e.g., substrate 715) shown in FIG. 7B. One or more other secondary optical components, such as a lens or a grating, may be formed on the light emission surface, such as substrate 715, to focus or collimate the emitted light and/or couple the emitted light into a waveguide.

One or two-dimensional arrays of the LEDs described above may be manufactured on a wafer to form light sources (e.g., light source 642). Drive circuits (e.g., drive circuit 644) may be fabricated, for example, on a silicon wafer using CMOS processes. The LEDs and the drive circuits on wafers may be diced and then bonded together, or may be bonded on the wafer level and then diced. Various bonding techniques can be used for bonding the LEDs and the drive circuits, such as adhesive bonding, metal-to-metal bonding, metal oxide bonding, wafer-to-wafer bonding, die-to-wafer bonding, hybrid bonding, and the like.

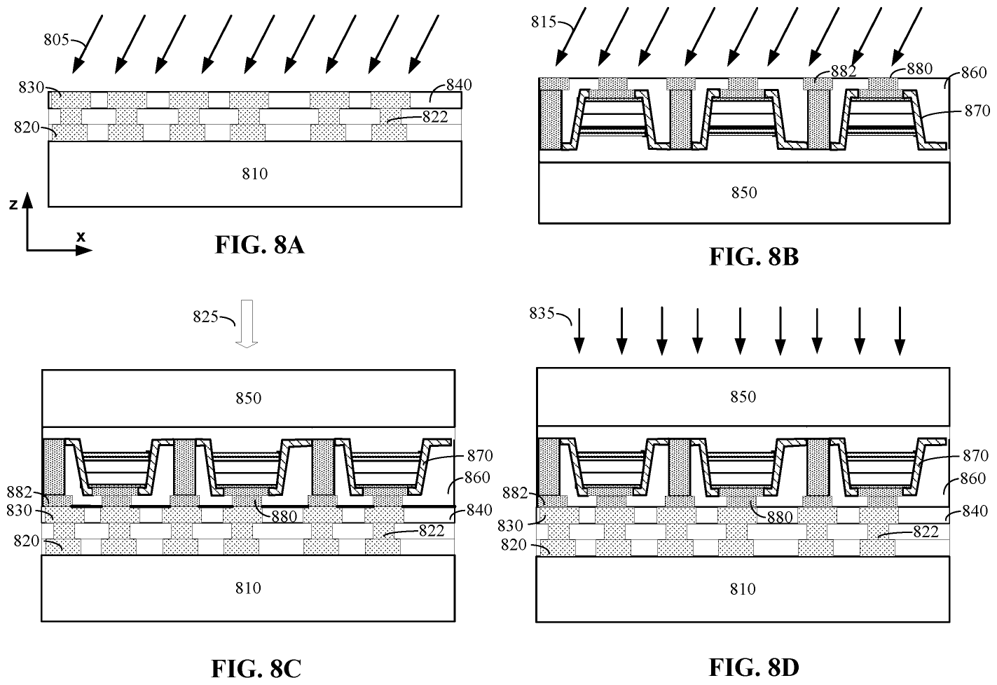

FIGS. 8A-8D illustrate an example of a method of hybrid bonding for arrays of LEDs according to certain embodiments. The hybrid bonding may generally include wafer cleaning and activation, high-precision alignment of contacts of one wafer with contacts of another wafer, dielectric bonding of dielectric materials at the surfaces of the wafers at room temperature, and metal bonding of the contacts by annealing at elevated temperatures. FIG. 8A shows a substrate 810 with passive or active circuits 820 manufactured thereon. As described above with respect to FIGS. 8A-8B, substrate 810 may include, for example, a silicon wafer. Circuits 820 may include drive circuits for the arrays of LEDs. A bonding layer may include dielectric regions 840 and contact pads 830 connected to circuits 820 through electrical interconnects 822. Contact pads 830 may include, for example, Cu, Ag, Au, Al, W, Mo, Ni, Ti, Pt, Pd, or the like. Dielectric materials in dielectric regions 840 may include SiCN, SiO₂, SiN, Al₂O₃, HfO₂, ZrO₂, Ta₂O₅, or the like. The bonding layer may be planarized and polished using, for example, chemical mechanical polishing, where the planarization or polishing may cause dishing (a bowl like profile) in the contact pads. The surfaces of the bonding layers may be cleaned and activated by, for example, an ion (e.g., plasma) or fast atom (e.g., Ar) beam 805. The activated surface may be atomically clean and may be reactive for formation of direct bonds between wafers when they are brought into contact, for example, at room temperature.

FIG. 8B illustrates a wafer 850 including an array of micro-LEDs 870 fabricated thereon as described above with respect to, for example, FIGS. 7A-8B. Wafer 850 may be a carrier wafer and may include, for example, GaAs, InP, GaN, AlN, sapphire, SiC, Si, or the like. Micro-LEDs 870 may include an n-type layer, an active region, and a p-type layer epitaxially grown on wafer 850. The epitaxial layers may include various III-V semiconductor materials described above, and may be processed from the p-type layer side to etch mesa structures in the epitaxial layers, such as substantially vertical structures, parabolic structures, conic structures, or the like. Passivation layers and/or reflection layers may be formed on the sidewalls of the mesa structures. P-contacts 880 and n-contacts 882 may be formed in a dielectric material layer 860 deposited on the mesa structures and may make electrical contacts with the p-type layer and the n-type layers, respectively. Dielectric materials in dielectric material layer 860 may include, for example, SiCN, SiO₂, SiN, Al₂O₃, HfO₂, ZrO₂, Ta₂O₅, or the like. P-contacts 880 and n-contacts 882 may include, for example, Cu, Ag, Au, Al, W, Mo, Ni, Ti, Pt, Pd, or the like. The top surfaces of p-contacts 880, n-contacts 882, and dielectric material layer 860 may form a bonding layer. The bonding layer may be planarized and polished using, for example, chemical mechanical polishing, where the polishing may cause dishing in p-contacts 880 and n-contacts 882. The bonding layer may then be cleaned and activated by, for example, an ion (e.g., plasma) or fast atom (e.g., Ar) beam 815. The activated surface may be atomically clean and reactive for formation of direct bonds between wafers when they are brought into contact, for example, at room temperature.

FIG. 8C illustrates a room temperature bonding process for bonding the dielectric materials in the bonding layers. For example, after the bonding layer that includes dielectric regions 840 and contact pads 830 and the bonding layer that includes p-contacts 880, n-contacts 882, and dielectric material layer 860 are surface activated, wafer 850 and micro-LEDs 870 may be turned upside down and brought into contact with substrate 810 and the circuits formed thereon. In some embodiments, compression pressure 825 may be applied to substrate 810 and wafer 850 such that the bonding layers are pressed against each other. Due to the surface activation and the dishing in the contacts, dielectric regions 840 and dielectric material layer 860 may be in direct contact because of the surface attractive force, and may react and form chemical bonds between them because the surface atoms may have dangling bonds and may be in unstable energy states after the activation. Thus, the dielectric materials in dielectric regions 840 and dielectric material layer 860 may be bonded together with or without heat treatment or pressure.

FIG. 8D illustrates an annealing process for bonding the contacts in the bonding layers after bonding the dielectric materials in the bonding layers. For example, contact pads 830 and p-contacts 880 or n-contacts 882 may be bonded together by annealing at, for example, about 200-400° C. or higher. During the annealing process, heat 835 may cause the contacts to expand more than the dielectric materials (due to different coefficients of thermal expansion), and thus may close the dishing gaps between the contacts such that contact pads 830 and p-contacts 880 or n-contacts 882 may be in contact and may form direct metallic bonds at the activated surfaces.

In some embodiments where the two bonded wafers include materials having different coefficients of thermal expansion (CTEs), the dielectric materials bonded at room temperature may help to reduce or prevent misalignment of the contact pads caused by the different thermal expansions. In some embodiments, to further reduce or avoid the misalignment of the contact pads at a high temperature during annealing, trenches may be formed between micro-LEDs, between groups of micro-LEDs, through part or all of the substrate, or the like, before bonding.

After the micro-LEDs are bonded to the drive circuits, the substrate on which the micro-LEDs are fabricated may be thinned or removed, and various secondary optical components may be fabricated on the light emitting surfaces of the micro-LEDs to, for example, extract, collimate, and redirect the light emitted from the active regions of the micro-LEDs. In one example, micro-lenses may be formed on the micro-LEDs, where each micro-lens may correspond to a respective micro-LED and may help to improve the light extraction efficiency and collimate the light emitted by the micro-LED. In some embodiments, the secondary optical components may be fabricated in the substrate or the n-type layer of the micro-LEDs. In some embodiments, the secondary optical components may be fabricated in a dielectric layer deposited on the n-type side of the micro-LEDs. Examples of the secondary optical components may include a lens, a grating, an antireflection (AR) coating, a prism, a photonic crystal, or the like.

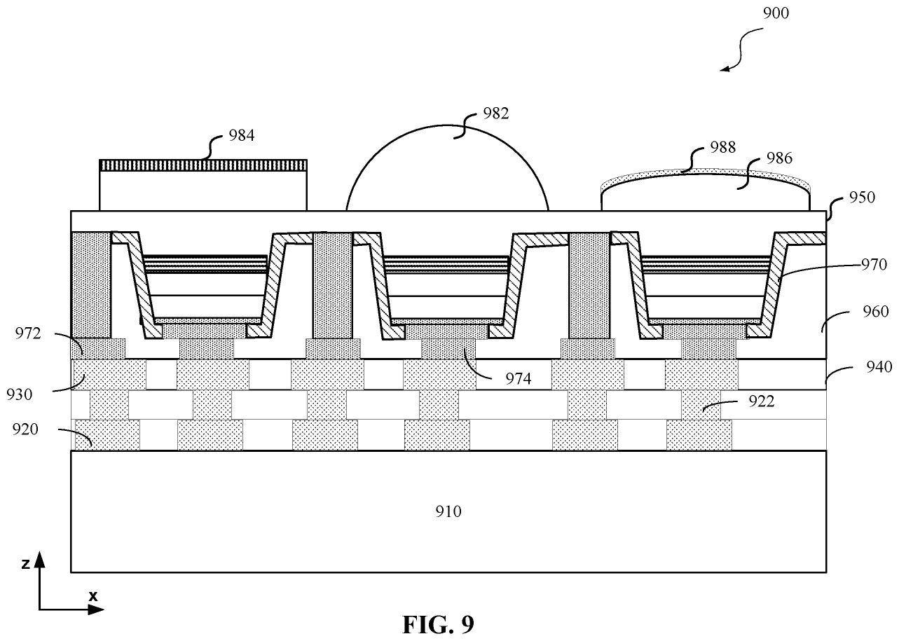

FIG. 9 illustrates an example of an LED array 900 with secondary optical components fabricated thereon according to certain embodiments. LED array 900 may be made by bonding an LED chip or wafer with a silicon wafer including electrical circuits fabricated thereon, using any suitable bonding techniques described above with respect to, for example, FIGS. 8A-8D. In the example shown in FIG. 9, LED array 900 may be bonded using a wafer-to-wafer hybrid bonding technique as described above with respect to FIG. 8A-8D. LED array 900 may include a substrate 910, which may be, for example, a silicon wafer. Integrated circuits 920, such as LED drive circuits, may be fabricated on substrate 910. Integrated circuits 920 may be connected to p-contacts 974 and n-contacts 972 of micro-LEDs 970 through interconnects 922 and contact pads 930, where contact pads 930 may form metallic bonds with p-contacts 974 and n-contacts 972. Dielectric layer 940 on substrate 910 may be bonded to dielectric layer 960 through fusion bonding.

The substrate (not shown) of the LED chip or wafer may be thinned or may be removed to expose the n-type layer 950 of micro-LEDs 970. Various secondary optical components, such as a spherical micro-lens 982, a grating 984, a micro-lens 986, an antireflection layer 988, and the like, may be formed in or on top of n-type layer 950. For example, spherical micro-lens arrays may be etched in the semiconductor materials of micro-LEDs 970 using a gray-scale mask and a photoresist with a linear response to exposure light, or using an etch mask formed by thermal reflowing of a patterned photoresist layer. The secondary optical components may also be etched in a dielectric layer deposited on n-type layer 950 using similar photolithographic techniques or other techniques. For example, micro-lens arrays may be formed in a polymer layer through thermal reflowing of the polymer layer that is patterned using a binary mask. The micro-lens arrays in the polymer layer may be used as the secondary optical components or may be used as the etch mask for transferring the profiles of the micro-lens arrays into a dielectric layer or a semiconductor layer. The dielectric layer may include, for example, SiCN, SiO₂, SiN, Al₂O₃, HfO₂, ZrO₂, Ta₂O₅, or the like. In some embodiments, a micro-LED 970 may have multiple corresponding secondary optical components, such as a micro-lens and an antireflection coating, a micro-lens etched in the semiconductor material and a micro-lens etched in a dielectric material layer, a micro-lens and a grating, a spherical lens and an aspherical lens, and the like. Three different secondary optical components are illustrated in FIG. 9 to show some examples of secondary optical components that can be formed on micro-LEDs 970, which does not necessary imply that different secondary optical components are used simultaneously for every LED array.

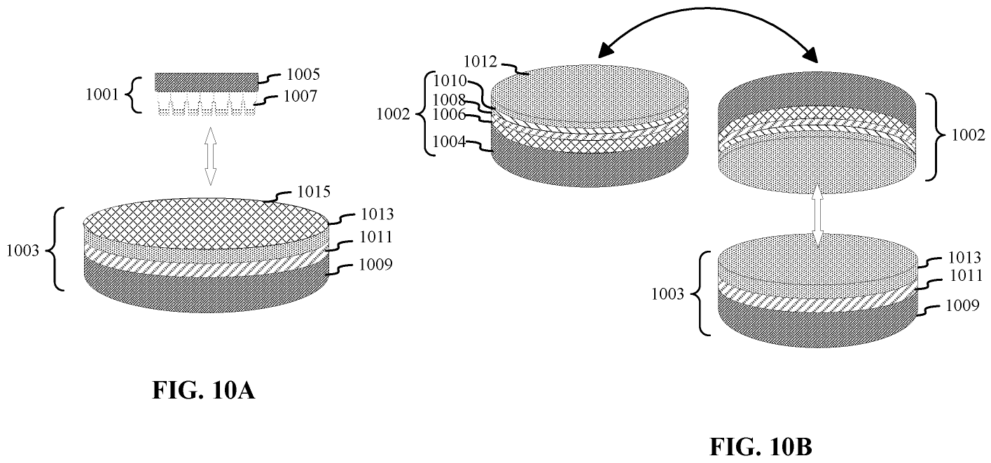

FIG. 10A illustrates an example of a method of die-to-wafer bonding for arrays of LEDs according to certain embodiments. In the example shown in FIG. 10A, an LED array 1001 may include a plurality of LEDs 1007 on a carrier substrate 1005. Carrier substrate 1005 may include various materials, such as GaAs, InP, GaN, AlN, sapphire, SiC, Si, or the like. LEDs 1007 may be fabricated by, for example, growing various epitaxial layers, forming mesa structures, and forming electrical contacts or electrodes, before performing the bonding. The epitaxial layers may include various materials, such as GaN, InGaN, (AlGaIn)P, (AlGaIn)AsP, (AlGaIn)AsN, (Eu:InGa)N, (AlGaIn)N, or the like, and may include an n-type layer, a p-type layer, and an active layer that includes one or more heterostructures, such as one or more quantum wells or MQWs. The electrical contacts may include various conductive materials, such as a metal or a metal alloy.

A wafer 1003 may include a base layer 1009 having passive or active integrated circuits (e.g., drive circuits 1011) fabricated thereon. Base layer 1009 may include, for example, a silicon wafer. Drive circuits 1011 may be used to control the operations of LEDs 1007. For example, the drive circuit for each LED 1007 may include a 2T1C pixel structure that has two transistors and one capacitor. Wafer 1003 may also include a bonding layer 1013. Bonding layer 1013 may include various materials, such as a metal, an oxide, a dielectric, CuSn, AuTi, and the like. In some embodiments, a patterned layer 1015 may be formed on a surface of bonding layer 1013, where patterned layer 1015 may include a metallic grid made of a conductive material, such as Cu, Ag, Au, Al, or the like.

LED array 1001 may be bonded to wafer 1003 via bonding layer 1013 or patterned layer 1015. For example, patterned layer 1015 may include metal pads or bumps made of various materials, such as CuSn, AuSn, or nanoporous Au, that may be used to align LEDs 1007 of LED array 1001 with corresponding drive circuits 1011 on wafer 1003. In one example, LED array 1001 may be brought toward wafer 1003 until LEDs 1007 come into contact with respective metal pads or bumps corresponding to drive circuits 1011. Some or all of LEDs 1007 may be aligned with drive circuits 1011, and may then be bonded to wafer 1003 via patterned layer 1015 by various bonding techniques, such as metal-to-metal bonding. After LEDs 1007 have been bonded to wafer 1003, carrier substrate 1005 may be removed from LEDs 1007.

For high-resolution micro-LED display panel, due to the small pitches of the micro-LED array and the small dimensions of individual micro-LEDs, it can be challenging to electrically connect the drive circuits to the electrodes of the LEDs. For example, in the face-to-face bonding techniques describe above, it is difficult to precisely align the bonding pads on the micro-LED devices with the bonding pads on the drive circuits and form reliable bonding at the interfaces that may include both dielectric materials (e.g., SiO₂, SiN, or SiCN) and metal (e.g., Cu, Au, or Al) bonding pads. In particular, when the pitch of the micro-LED device is about 2 or 3 microns or lower, the bonding pads may have a linear dimension less than about 1 μm in order to avoid shorting to adjacent micro-LEDs and to improve bonding strength for the dielectric bonding. However, small bonding pads may be less tolerant to misalignments between the bonding pads, which may reduce the metal bonding area, increase the contact resistance (or may even be an open circuit), and/or cause diffusion of metals to the dielectric materials and the semiconductor materials. Thus, precise alignment of the bonding pads on surfaces of the micro-LED arrays and bonding pads on surfaces of CMOS backplane may be needed in the conventional processes. However, the accuracy of die-to-wafer or wafer-to-wafer bonding alignment using state-of-art equipment may be on the order of about 0.5 μm or about 1μm, which may not be adequate for bonding the small-pitch micro-LED arrays (e.g., with a linear dimension of the bonding pads on the order of 1μm or shorter) to CMOS drive circuits.

In some implementations, to avoid precise alignment for the bonding, a micro-LED wafer may be bonded to a CMOS backplane after the epitaxial layer growth and before the formation of individual micro-LED on the micro-LED wafer, where the micro-LED wafer and the CMOS backplane may be bonded through metal-to-metal bonding of two solid metal bonding layers on the two wafers. No alignment would be needed to bond the solid contiguous metal bonding layers. After the bonding, the epitaxial layers on the micro-LED wafer and the metal bonding layers may be etched to form individual micro-LEDs. The etching process may have much higher alignment accuracy and thus may form individual micro-LEDs that align with the underlying pixel drive circuits.

FIG. 10B illustrates an example of a method of wafer-to-wafer bonding for arrays of LEDs according to certain embodiments. As shown in FIG. 10B, a first wafer 1002 may include a substrate 1004, a first semiconductor layer 1006, active layers 1008, and a second semiconductor layer 1010. Substrate 1004 may include various materials, such as GaAs, InP, GaN, AlN, sapphire, SiC, Si, or the like. First semiconductor layer 1006, active layers 1008, and second semiconductor layer 1010 may include various semiconductor materials, such as GaN, InGaN, (AlGaIn)P, (AlGaIn)AsP, (AlGaIn)AsN, (AlGaIn)Pas, (Eu:InGa)N, (AlGaIn)N, or the like. In some embodiments, first semiconductor layer 1006 may be an n-type layer, and second semiconductor layer 1010 may be a p-type layer. For example, first semiconductor layer 1006 may be an n-doped GaN layer (e.g., doped with Si or Ge), and second semiconductor layer 1010 may be a p-doped GaN layer (e.g., doped with Mg, Ca, Zn, or Be). Active layers 1008 may include, for example, one or more GaN layers, one or more InGaN layers, one or more AlInGaP layers, and the like, which may form one or more heterostructures, such as one or more quantum wells or MQWs.

In some embodiments, first wafer 1002 may also include a bonding layer. Bonding layer 1012 may include various materials, such as a metal, an oxide, a dielectric, CuSn, AuTi, or the like. In one example, bonding layer 1012 may include p-contacts and/or n-contacts (not shown). In some embodiments, other layers may also be included on first wafer 1002, such as a buffer layer between substrate 1004 and first semiconductor layer 1006. The buffer layer may include various materials, such as polycrystalline GaN or AlN. In some embodiments, a contact layer may be between second semiconductor layer 1010 and bonding layer 1012. The contact layer may include any suitable material for providing an electrical contact to second semiconductor layer 1010 and/or first semiconductor layer 1006.

First wafer 1002 may be bonded to wafer 1003 that includes drive circuits 1011 and bonding layer 1013 as described above, via bonding layer 1013 and/or bonding layer 1012. Bonding layer 1012 and bonding layer 1013 may be made of the same material or different materials. Bonding layer 1013 and bonding layer 1012 may be substantially flat. First wafer 1002 may be bonded to wafer 1003 by various methods, such as metal-to-metal bonding, eutectic bonding, metal oxide bonding, anodic bonding, thermo-compression bonding, ultraviolet (UV) bonding, and/or fusion bonding.

As shown in FIG. 10B, first wafer 1002 may be bonded to wafer 1003 with the p-side (e.g., second semiconductor layer 1010) of first wafer 1002 facing down (i.e., toward wafer 1003). After bonding, substrate 1004 may be removed from first wafer 1002, and first wafer 1002 may then be processed from the n-side. The processing may include, for example, the formation of certain mesa shapes for individual LEDs, as well as the formation of optical components corresponding to the individual LEDs.

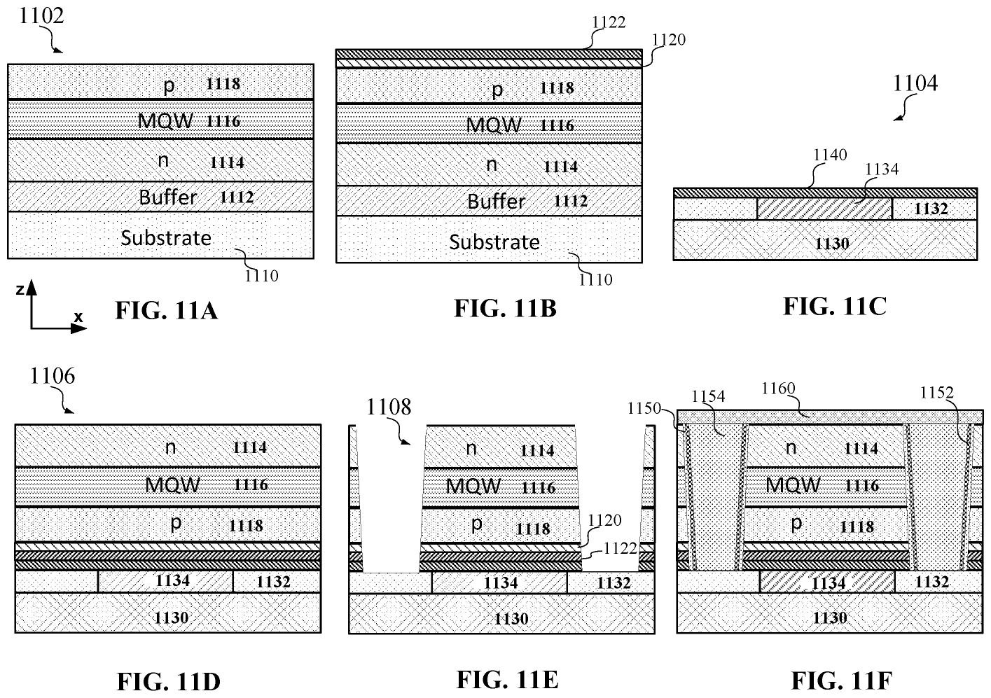

FIGS. 11A-11F illustrate an example of a method of fabricating a micro-LED device using alignment-free metal-to-metal bonding and post-bonding mesa formation processes. FIG. 11A shows a micro-LED wafer 1102 including epitaxial layers grown on a substrate 1110. As described above, substrate 1110 may include, for example, a GaN, GaAs, or GaP substrate, or a substrate including, but not limited to, sapphire, silicon carbide, silicon, zinc oxide, boron nitride, lithium aluminate, lithium niobate, germanium, aluminum nitride, lithium gallate, partially substituted spinels, or quaternary tetragonal oxides sharing the beta-LiAlO₂ structure, where the substrate may be cut in a specific direction to expose a specific plane (e.g., a c-plane or a semipolar plane) as the growth surface. In some embodiments, a buffer layer 1112 may be formed on substrate 1110 to improve the lattice matching between the growth substrate and the epitaxial layers, thereby reducing stress and defects in the epitaxial layers. The epitaxial layers may include an n-type semiconductor layer 1114 (e.g., a GaN layer doped with Si or Ge), an active region 1116, and a p-type semiconductor layer 1118 (e.g., a GaN layer doped with Mg, Ca, Zn, or Be). Active region 1116 may include multiple quantum wells or an MQW formed by quantum well layers (e.g., InGaN layer) sandwiched by barrier layers (e.g., GaN layer) as described above. The epitaxial layers may be grown layer-by-layer on substrate 1110 or buffer layer 1112 using techniques such as VPE, LPE, MBE, or MOCVD.

In the epitaxial growth processes, dopants (e.g., Mg) used to dope the p-type semiconductor layer (e.g., Mg-doped GaN layer) may remain in the reactor and/or on the epitaxial surface after the introduction of Mg precursors into the reactor. For example, the source for Mg doping (e.g., bis(cyclopentadienyl) magnesium (Cp2Mg)) may be adsorbed onto reactor lines and walls and may be released in the gas phase in subsequent processes. A surface riding effect can also contribute to the residual Mg due to a Mg-rich layer formed on the surface of the p-GaN layer. Thus, if the quantum-well layers are grown on the Mg-rich p-GaN layer after the growth of the p-GaN layer with Mg dopants, the quantum-well layers may be contaminated with Mg dopants even after the Mg source is turned off, which may be referred to as the Mg-memory effect and may manifest as a slow decay tail of Mg into subsequent epitaxial layers. Mg can contaminate the MQW layers to form non-radiative recombination centers caused by, for example, Mg-related point defects, Mg interstitials, or Mg-related complexes.

In addition, for p-type GaN layers formed using, for example, MOCVD, the dopants (e.g., Mg) may be passivated due to the incorporation of atomic hydrogen (which exists in the form of H⁺ ) during growth and the formation of Mg-H complexes. Therefore, a post-growth activation of the dopants is generally performed to release mobile holes. The activation of the dopants in the p-GaN layer may include breaking the Mg—H bonds and driving the H⁺ out of the p-GaN layer at elevated temperatures (e.g., above 700° C.) to activate the Mg dopants. Insufficient activation of the Mg dopants in the p-GaN layer may lead to an open circuit, a poor performance, or a premature punch-through breakdown of the LED device. If p-type GaN layer is grown before the growth of the active region and the n-type layer, to drive out hydrogen, positively charged H⁺ ions need to diffuse across the p-n junction and through the n-GaN layer that is exposed. However, because of the depletion field in the p-n junction (with a direction from the n-type layer to the p-type layer), positively charged H⁺ ions may not be able to diffuse from the p-type layer to the n-type layer across the p-n junction. Furthermore, hydrogen may have a much higher diffusion barrier and thus a much lower diffusivity in n-type GaN compared with in p-type GaN. Thus, the hydrogen ions may not diffuse through the n-type layer to the exposed top surface of the n-type layer. Moreover, the activation may not be performed right after the p-doping and before the growth of the active region either, because the subsequent growth may be performed in the presence of high pressure ammonia (NH₃) in order to avoid decomposition of GaN at the high growth temperatures, and thus a semiconductor layer (e.g., the p-type semiconductor layer) that was activated may be re-passivated due to the presence of ammonia.

Therefore, in general, during the growth of the epitaxial layers, n-type semiconductor layer 1114 may be grown first. P-type semiconductor layer 1118 may be grown after the growth of active region 1116 to avoid contamination of active region 1116 and facilitate activation of the dopants in the p-type semiconductor layer.

FIG. 11B shows a reflector layer 1120 and a bonding layer 1122 formed on p-type semiconductor layer 1118. Reflector layer 1120 may include, for example, a metal layer such as an aluminum layer, a silver layer, or a metal alloy layer. In some embodiments, reflector layer 1120 may include a distributed Bragg reflector formed by conductive materials (e.g., semiconductor materials or conductive oxides) or including conductive vias. In some embodiments, reflector layer 1120 may include one or more sublayers. Reflector layer 1120 may be formed on p-type semiconductor layer 1118 in a deposition process. Bonding layer 1122 may include a metal layer, such as a titanium layer, a copper layer, an aluminum layer, a gold layer, or a metal alloy layer. In some embodiments, bonding layer 1122 may include a eutectic alloy, such as Au—In, Au—Sn, Au—Ge, or Ag—In. Bonding layer 1122 may be formed on reflector layer 1120 by a deposition process and may include one or more sublayers.

FIG. 11C shows a backplane wafer 1104 that includes a substrate 1130 with electrical circuits formed thereon. The electrical circuits may include digital and analog pixel drive circuits for driving individual micro-LEDs. A plurality of metal pads 1134 (e.g., copper or tungsten pads) may be formed in a dielectric layer 1132 (e.g., including SiO₂ or SiN). In some embodiments, each metal pad 1134 may be an electrode (e.g., anode or cathode) for a micro-LED. In some embodiments, pixel drive circuits for each micro-LED may be formed in an area matching the size of a micro-LED (e.g., about 2 μm×2 μm), where the pixel drive circuits and the micro-LED may collectively form a pixel of a micro-LED display panel. Even though FIG. 11C only shows metal pads 1134 formed in one metal layer in one dielectric layer 1132, backplane wafer 1104 may include two or more metal layers formed in dielectric materials and interconnected by, for example, metal vias, as in many CMOS integrated circuits. In some embodiments, a planarization process, such as a chemical mechanical polishing (CMP) process, may be performed to planarize the exposed surfaces of metal pads 1134 and dielectric layer 1132. A bonding layer 1140 may be formed on dielectric layer 1132 and may be in physical and electrical contact with metal pads 1134. As bonding layer 1122, bonding layer 1140 may include a metal layer, such as a titanium layer, a copper layer, an aluminum layer, a gold layer, a metal alloy layer, or a combination thereof. In some embodiments, bonding layer 1140 may include a eutectic alloy. In some embodiments, only one of bonding layer 1140 or bonding layer 1122 may be used.

FIG. 11D shows that micro-LED wafer 1102 and backplane wafer 1104 may be bonded together to form a wafer stack 1106. Micro-LED wafer 1102 and backplane wafer 1104 may be bonded by the metal-to-metal bonding of bonding layer 1122 and bonding layer 1140. The metal-to-metal bonding may be based on chemical bonds between the metal atoms at the surfaces of the metal bonding layers. The metal-to-metal bonding may include, for example, thermo-compression bonding, eutectic bonding, or transient liquid phase (TLP) bonding. The metal-to-metal bonding process may include, for example, surface planarization, wafer cleaning (e.g., using plasma or solvents) at room temperatures, and compression and annealing at elevated temperatures, such as about 250° C. or higher, to cause diffusion of atoms. In eutectic bonding, a eutectic alloy including two or more metals and with a eutectic point lower than the melting point of the two or more metals may be used for low-temperature wafer bonding. Because the eutectic alloy may become a liquid at the elevated temperature, eutectic bonding may be less sensitive to surface flatness irregularities, scratches, particles contamination, and the like. After the bonding, buffer layer 1112 and substrate 1110 may be thinned or removed by, for example, etching, back grinding, or laser lifting, to expose n-type semiconductor layer 1114.

FIG. 11E shows that wafer stack 1106 may be etched from the side of the exposed n-type semiconductor layer 1114 to form mesa structures 1108 for individual micro-LEDs. As shown in FIG. 11E, the etching may include etching through n-type semiconductor layer 1114, active region 1116, p-type semiconductor layer 1118, reflector layer 1120, and bonding layers 1122 and 1140, in order to singulate and electrically isolate mesa structures 1108. Thus, each singulated mesa structure 1108 may include n-type semiconductor layer 1114, active region 1116, p-type semiconductor layer 1118, reflector layer 1120, and bonding layers 1122 and 1140. To perform the etching, an etch mask layer may be formed on n-type semiconductor layer 1114. The etch mask layer may be patterned by aligning a photomask with the backplane wafer (e.g., using alignment marks on backplane wafer 1104) such that the patterned etch mask formed in the etch mask layer may align with metal pads 1134. Therefore, regions of the epitaxial layers and bonding layers above metal pads 1134 may not be etched. Dielectric layer 1132 may be used as the etch-stop layer for the etching. Even though FIG. 11E shows that mesa structures 1108 have substantially vertical sidewalls, mesa structures 1108 may have other shapes as described above, such as a conical shape, a parabolic shape, or a truncated pyramid shape.

FIG. 11F shows that a passivation layer 1150 may be formed on sidewalls of mesa structures 1108, and a sidewall reflector layer 1152 may be formed on passivation layer 1150. Passivation layer 1150 may include a dielectric layer (e.g., SiO2, SiN, or Al2O3) or an undoped semiconductor layer. Sidewall reflector layer 1152 may include, for example, a metal (e.g., Al) or a metal alloy. In some embodiments, gaps between mesa structures 1108 may be filled with a dielectric material 1154 and/or a metal. Passivation layer 1150, sidewall reflector layer 1152, and/or dielectric material 1154 may be formed using suitable deposition techniques, such as chemical vapor deposition (CVD), physical vapor deposition (PVD), plasma-enhanced chemical vapor deposition (PECVD), atomic-layer deposition (ALD), laser metal deposition (LIVID), or sputtering. In some embodiments, sidewall reflector layer 1152 may fill the gaps between mesa structures 1108. In some embodiments, a planarization process may be performed after the deposition of passivation layer 1150, sidewall reflector layer 1152, and/or dielectric material 1154. A common electrode layer 1160, such as a transparent conductive oxide (TCO) layer (e.g., an ITO layer) or a thin metal layer that may be transparent to light emitted in active region 1116, may be formed on the n-type semiconductor layer 1114 to form n-contacts and a common-cathode for the micro-LEDs. Even though not shown in FIG. 11F, an array of micro-lenses may be formed on common electrode layer 1160 to extract and collimate light emitted in active region 1116.

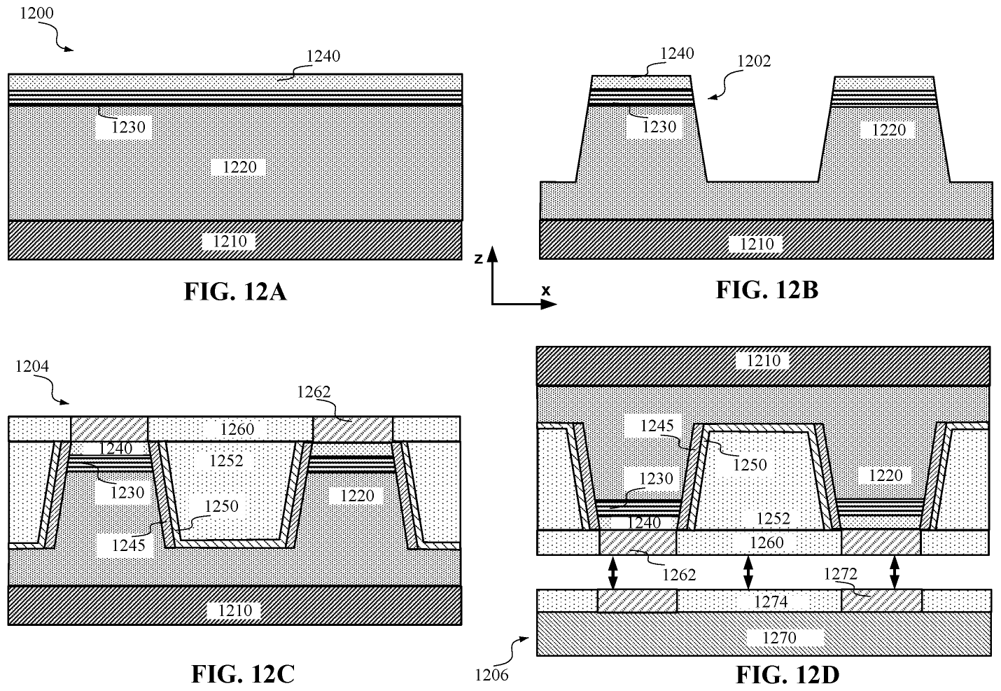

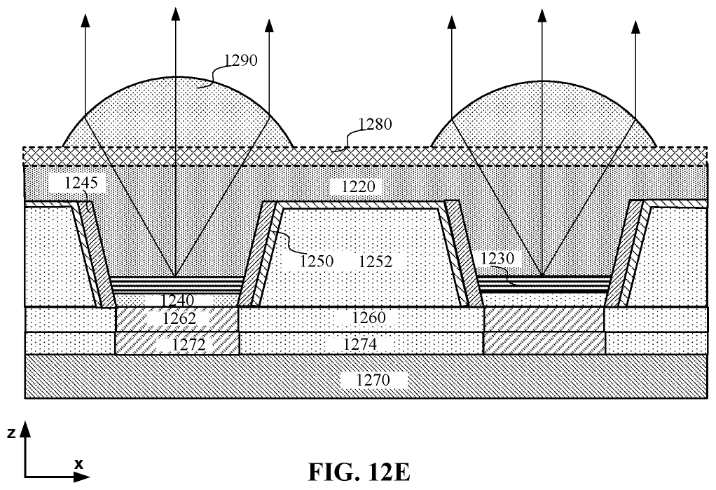

FIGS. 12A-12E illustrate an example of a process of fabricating a micro-LED device according to certain embodiments. FIG. 12A shows a micro-LED wafer 1200 including epitaxial layers grown on a substrate 1210. As described above, substrate 1210 may include, for example, a GaN, GaAs, or GaP substrate, or a substrate including, but not limited to, sapphire, silicon carbide, silicon, zinc oxide, boron nitride, lithium aluminate, lithium niobate, germanium, aluminum nitride, lithium gallate, partially substituted spinels, or quaternary tetragonal oxides sharing the beta-LiAlO₂ structure, where the substrate may be cut in a specific direction to expose a specific plane (e.g., a c-plane or a semipolar plane) as the growth surface. In some embodiments, a buffer layer may be formed on substrate 1210 to improve the lattice matching between the growth substrate and the epitaxial layers, thereby reducing stress and defects in the epitaxial layers. The epitaxial layers may include an n-type semiconductor layer 1220 (e.g., an n-doped GaN, AlInP, or AlGaInP layer), an active region 1230, and a p-type semiconductor layer 1240 (e.g., a p-doped GaN, AlInP, or AlGaInP layer). Active region 1230 may include multiple quantum wells or an MQW formed by thin quantum well layers (e.g., InGaN layers or GaInP layers) sandwiched by barrier layers (e.g., GaN layers, AlInP layers, or AlGaInP layers) as described above. The epitaxial layers may be grown layer-by-layer on substrate 1210 or the buffer layer using techniques such as VPE, LPE, MBE, or MOCVD. In some embodiments, n-type semiconductor layer 1220 may be much thicker than p-type semiconductor layer 1240.

FIG. 12B shows that micro-LED wafer 1200 may be etched from the side of p-type semiconductor layer 1240 to form semiconductor mesa structures 1202 for individual micro-LEDs. As shown in FIG. 12B, the etching may include etching through p-type semiconductor layer 1240, active region 1230, and at least a portion of n-type semiconductor layer 1220. Thus, each semiconductor mesa structure 1202 may include p-type semiconductor layer 1240, active region 1230, and a portion of n-type semiconductor layer 1220. To perform the etching, an etch mask layer may be formed on p-type semiconductor layer 1240, and dry or wet etching may be performed from the side of p-type semiconductor layer 1240. Due to the etching from p-type semiconductor layer 1240, semiconductor mesa structure 1202 may have sidewalls that are inwardly tilted in the z direction. For example, the angle between the sidewalls and the surface-normal direction (the z direction) of micro-LED wafer 1200 may be between about 0° to about 30°, such as about 15°. In some embodiments, semiconductor mesa structures 1202 may have a conical shape, a parabolic shape, a truncated pyramid shape, or another shape. In some embodiments, after the etching, sidewalls of the etched semiconductor mesa structures 1202 may be treated, for example, using KOH or an acid, to remove regions that may be damaged by high-energy ions during the dry etching.

FIG. 12C shows that micro-LED wafer 1200 may be further processed from the side of p-type semiconductor layer 1240 to form a wafer 1204 that includes an array of micro-LEDs. In the illustrated example, a passivation layer 1245 may be formed on sidewalls of semiconductor mesa structures 1202. Passivation layer 1245 may include, for example, SiO₂, SiN, Al₂O₃, or a semiconductor material. Passivation layer 1245 may electrically isolate semiconductor mesa structures 1202. A reflective metal layer 1250 (e.g., Al, Au, Ag, Cu, Ti, Ni, Pt, or a combination thereof) may be formed on passivation layer 1245 to optically isolate individual micro-LEDs and improve the light extraction efficiency. In some embodiments, reflective metal layer 1250 may fill regions between semiconductor mesa structures 1202. In some embodiments, a dielectric material 1252 (e.g., SiO₂) may be deposited on reflective metal layer 1250 and regions between semiconductor mesa structures 1202. Passivation layer 1245, reflective metal layer 1250, and dielectric material 1252 may be formed using suitable deposition techniques, such as chemical vapor deposition (CVD), physical vapor deposition (PVD), plasma-enhanced chemical vapor deposition (PECVD), atomic-layer deposition (ALD), laser metal deposition (LIVID), or sputtering. A back reflector and p-contact 1262 may be form in a dielectric material 1260 and may contact p-type semiconductor layer 1240 of a corresponding semiconductor mesa structure 1202. Back reflector and p-contact 1262 may include, for example, Au, Ag, Al, Ti, Cu, Ni, ITO, or a combination thereof. Even though not shown in FIG. 12C, in some embodiments, one or more metal interconnect layers may be formed on back reflector and p-contact 1262. The one or more metal interconnect layers may include a bonding layer that includes metal bonding pads in a dielectric layer as described above with respect to, for example, FIG. 8B.

FIG. 12D shows that wafer 1204 may be bonded to a backplane wafer 1206 in a hybrid bonding process. Backplane wafer 1206 may include a substrate 1270 with electrical circuits formed thereon. The electrical circuits may include digital and analog pixel drive circuits for driving individual micro-LEDs. A plurality of metal pads 1272 (e.g., copper or tungsten pads) may be formed in a dielectric layer 1274 (e.g., including SiO₂ or SiN). In some embodiments, each metal pad 1272 may be an electrode (e.g., anode or cathode) for a micro-LED. Even though FIG. 12D only shows metal pads 1272 formed in one metal layer in one dielectric layer 1274, backplane wafer 1206 may include two or more metal layers formed in dielectric materials and interconnected by, for example, metal vias, as in many CMOS integrated circuits.

As described above with respect to, for example, FIGS. 8A-8D, the bonding surfaces of wafer 1204 and backplane wafer 1206 may be planarized, cleaned, and activated before the bonding. Wafer 1204 may be turned upside down and brought into contact with backplane wafer 1206 such that dielectric layer 1274 and dielectric material 1260 may be in direct contact and may be bonded together with or without heat treatment due to the surface activation. In some embodiments, a compression pressure may be applied to wafer 1204 and backplane wafer 1206 such that the bonding layers are pressed against each other. After the bonding of the dielectric materials, an annealing process may be performed at an elevated temperature to bond the metal pads (e.g., back reflector and p-contacts 1262 and metal pads 1272) at the bonding surfaces.

FIG. 12E shows that, after the bonding of wafer 1204 and backplane wafer 1206, substrate 1210 of wafer 1204 may be removed, and a transparent conductive oxide (TCO) layer 1280 (e.g., such as an ITO layer) may optionally be formed on the exposed n-type semiconductor layer 1220. TCO layer 1280 may form a common cathode for the micro-LEDs. In the illustrated example, non-native lenses 1290 may be fabricated in a dielectric material (e.g., SiN or SiO₂) or an organic material, and may be bonded to TCO layer 1280. In some embodiments, non-native lenses 1290 may be fabricated in a dielectric material deposited on TCO layer 1280. In some embodiments, native lenses may be fabricated in n-type semiconductor layer 1220, and the common cathode may be formed on the native lenses and/or may be the portion of n-type semiconductor layer 1220 that has not been etched (which can be heavily doped to reduce the resistance). As shown in FIGS. 12D and 12E, since wafer 1204 is turned upside down and bonded to backplane wafer 1206 and light may exit the micro-LEDs from the side of n-type semiconductor layer 1220, the semiconductor mesa structures of the micro-LEDs may have sidewalls that are outwardly tilted in the light emitting direction (e.g., the z direction).

As described above, in semiconductor LEDs, photons are usually generated at a certain internal quantum efficiency through the recombination of electrons and holes within an active region (e.g., one or more semiconductor layers), where the internal quantum efficiency is the proportion of the radiative electron-hole recombination in the active region that emits photons. The generated light may then be extracted from the LEDs in a particular direction or within a particular solid angle. The ratio between the number of emitted photons extracted from an LED and the number of electrons passing through the LED is referred to as the external quantum efficiency, which describes how efficiently the LED converts injected electrons to photons that are extracted from the device. The external quantum efficiency may be proportional to the injection efficiency, the internal quantum efficiency, and the extraction efficiency. The injection efficiency refers to the proportion of electrons passing through the device that are injected into the active region. The extraction efficiency is the proportion of photons generated in the active region that escape from the device. For LEDs, and in particular, micro-LEDs including small semiconductor mesa structures formed in epitaxial layers to singulate the micro-LEDs, improving the internal and external quantum efficiency and/or controlling the emission spectrum may be challenging.

The internal quantum efficiency may indicate the proportion of the radiative electron-hole recombination in the active region that emits photons. The internal quantum efficiency of LEDs may depend on the relative rates of competitive radiative (light producing) recombination and non-radiative (lossy) recombination that occur in the active region of the LEDs. Non-radiative recombination processes in the active region may include Shockley-Read-Hall (SRH) recombination at defect sites and eeh/ehh Auger recombination that involves three carriers. The internal quantum efficiency of an LED may be approximately determined by:

$$I Q E = \frac{B {N}^{2}}{A N + B {N}^{2} + C {N}^{3}} , \qquad ( 1 )$$

where A, B and C are the rates of SRH recombination, bimolecular (radiative) recombination, and Auger recombination, respectively, and Nis the charge-carrier density (i.e., charge-carrier concentration) in the active region.

Auger recombination may be a major cause of efficiency droop and may be direct or indirect. For example, direct Auger recombination occurs when an electron and a hole recombine, but instead of producing light, either an electron is raised higher into the conduction band or a hole is pushed deeper into the valence band. Auger recombination may be reduced to mitigate the efficiency droop by lowering the charge-carrier density N in the active region for a given injection current density J, which may be written as:

J=qd_{eff}(AN+BN²+CN³), (2)

where d_{eff} is the effective thickness of the active region. Thus, according to equation (2), the effect of the Auger recombination may be reduced and thus the IQE of the LED may be improved by reducing the charge-carrier density N for a given injection current density, which may be achieved by increasing the effective thickness of the active region d_{eff}. The effective thickness of the active region may be increased by, for example, growing multiple quantum wells (MQWs). Alternatively, an active region including a single thick double heterostructure (DH) may be used to increase the effective thickness of the active region.

One factor affecting the effective thickness of the active region is the presence of internal fields E_{qw} (e.g., strain-induced internal field) in the quantum wells. Internal fields E_{qw} may localize charge carriers and reduce the overlap integral between carrier wave functions, which may reduce the radiative efficiency of LEDs. Some LEDs including heterostructures (e.g., quantum wells) may have a strong internal strain-induced piezoelectric field in the carrier transport direction. The strain-induced internal field may cause the electron and hole energy levels to shift (thus changing the bandgap) and cause the electrons and holes to shift to opposite sides of a quantum well, thereby decreasing the spatial electron-hole overlap and reducing the radiative recombination efficiency and thus the internal quantum efficiency of the LED.

While the Auger recombination due to a high current density (and high charge carrier density) may be an intrinsic process depending on material properties, non-radiative SRH recombination depends on the characteristics and the quality of material, such as the defect density in the active region. As described above with respect to FIGS. 7A and 7B, LEDs may be fabricated by etching mesa structures into the active emitting layers to confine carriers within the mesa structures of the individual LEDs and to expose the n-type material beneath the active emitting layers for electrical contact. When mesa structures are etched (e.g., using high-energy ions such as Ar⁺, Cl₂⁺, Cl⁺, or H⁺) to isolate individual LEDs, the facets of the mesa structure, such as mesa sidewalls 732, may include some defects, such as lattice dislocations, dangling bonds, pores, grain boundaries, vacancies, surface oxides, surfaces modified by plasma atoms, interstitial defects, substitutional defects, inclusion of precipitates, and the like. The defects may create energy levels that otherwise would not exist within the bandgap of the semiconductor material, causing non-radiative electron-hole recombination at or near the facets of the mesa structure. Thus, these imperfections may become the recombination centers where electrons and holes may be confined until they combine non-radiatively. Therefore, the active region in proximity to the exposed sidewalls may have a higher rate of non-radiative SRH recombination, thereby reducing the efficiency of the resulting LED. Due to the small size of the mesa structure, a larger proportion of the injected carriers may diffuse to regions near the mesa sidewalls and may be subjected to a higher non-radiative recombination rate. This may cause the peak efficiency of the LED to decrease significantly and/or cause the peak efficiency operating current to increase.

Parameters that may affect the impact of the non-radiative surface recombination on the LED efficiency may include, for example, the surface recombination velocity (SRV) S, the carrier diffusion coefficient (diffusivity) D, and the carrier lifetime r. The high recombination rate in the vicinity of the sidewalls due to the high defect density may depend on the number of excess carriers (in particular, the minority carriers) in the region. The high recombination rate may deplete the carriers in the region. The depletion of the carriers in the region may cause carriers to diffuse to the region from surrounding regions with higher carrier concentrations. Thus, the amount of surface recombination may depend on the surface recombination velocity S at which carriers move to the regions near the sidewalls. The carrier lifetime τ is the average time that a carrier can spend in an excited state after the electron-hole generation but before the carrier recombines with another carrier. The carrier lifetime τ generally depends on the carrier concentration and the recombination rate in the active region. The carrier diffusion coefficient D of the material and the carrier lifetime τ may determine the carrier diffusion length L=\sqrt{D×τ}, which is the average distance a carrier can travel from the time of generation until it recombines with another carrier. The carrier diffusion length L characterizes the width of the region that is adjacent to a sidewall surface of the active region and where the contribution of surface recombination to the carrier losses is significant. Charge carriers injected or diffused into the regions that are within a minority carrier diffusion length from the sidewall surfaces may be subject to the higher SRH recombination rate. III-phosphide materials, such as AlGaInP, can have a high surface recombination velocity and minority carrier diffusion length. For example, carriers in AlGaInP can have high diffusivity (mobility), and AlGaInP may have an order of magnitude higher surface recombination velocity than III-nitride materials.

A higher current density (e.g., in units of amps/cm2) may associate with a lower surface recombination velocity as the surface defects may be more and more saturated at higher carrier densities. Thus, the surface recombination velocity may be reduced by increasing the current density. In addition, the diffusion length of a given material may vary with the current density at which the device is operated. However, LEDs generally may not be able operate at very high current densities. Increasing the current injection may also cause the efficiencies of the micro-LEDs to drop due to the higher Auger recombination rate and the lower conversion efficiency at higher temperatures caused by self-heating at the higher current density.

For traditional, broad area LEDs used in lighting and backlighting applications (e.g., with a lateral device area about 0.1 mm² to about 1 mm²), the sidewalls are at the far ends of the devices. The devices can be designed such that little or no current is injected into regions within a minority carrier diffusion length from the mesa sidewalls, and thus the sidewall surface area to volume ratio and the overall rate of SRH recombination may be low. However, in micro-LEDs, as the size of the LED is reduced to a value comparable to or having a same order of magnitude as the minority carrier diffusion length, the increased surface area to volume ratio may lead to a high carrier surface recombination rate, because a greater proportion of the total active region may fall within the minority carrier diffusion length from the LED sidewalls. Therefore, more injected carriers may be subjected to the higher SRH recombination rate. This can cause the leakage current of the LED to increase and the efficiency of the LED to decrease as the size of the LED decreases, and/or cause the peak efficiency operating current to increase as the size of the LED decreases. For example, for a first LED with a 100 μm×100 μm×2 μm mesa, the side-wall surface area to volume ratio may be about 0.04. However, for a second LED with a 5 μm×5 μm×2 μm mesa, the side wall surface area to volume ratio may be about 0.8, which is about 20 times higher than the first LED. Thus, with a similar surface defect density, the SRH recombination coefficient of the second LED may be about 20 times higher as well. Therefore, the efficiency of the second LED may be significantly lower than the first LED.

In addition, at the light-emitting surface of an LED, such as the interface between the LED and air, incident light with incident angles greater than a critical angle may be reflected back to the LED due to total internal reflection (TIR). Because of the geometry of the LED, some light reflected back to the LED may be trapped and eventually be absorbed by the LED. For example, some trapped light may be absorbed by the semiconductor materials to generate electron-hole pairs, which may recombine radiatively or non-radiatively. Some trapped light may be absorbed by metals (e.g., metal contacts or reflectors) at the bottom and/or sidewalls of the LED due to, for example, surface plasmon resonance that may be excited by p-polarized light at the interface between a metal layer and a dielectric layer (e.g., the passivation layer). Because of the high refractive indices of many III-V semiconductor materials (e.g., about 2.4 for GaN, and greater than about 3.0 for GaP, InP, GaInP, and AlGaInP), the critical angle for total internal reflection at the interface between the III-V semiconductor material and an adjacent lower refractive index material (e.g., air or a dielectric) may be small. As such, a large portion of the light emitted in the active region of a III-V material-based LED may be trapped in the LED due to TIR and may eventually be absorbed by the LED. Therefore, the LEE of the micro-LED may be low. In large LEDs, the light extraction efficiency may be improved by using, for example, thin film technology or patterned sapphire substrates with dense, periodic patterns on the substrate surfaces, or rough light emitting surface, to randomize the propagation directions of the photons and increase the possibility of the photons being released from the confinement and exiting the mesa structure. However, these techniques may not be used in micro-LEDs with linear dimensions less than, for example, about 5 μm or about 3 μm, due to the small sizes and high aspect ratios (height vs width) of these micro-LEDs. For example, roughening the light emitting surface using KOH may generate features with sizes about a few microns, which may be comparable to or larger than the size of the mesa structure of a micro-LED, and thus may not randomize the incident light and may divert the incident light differently at different micro-LEDs.

Core-shell nanowire micro-LEDs with epitaxially grown active regions may have high IQEs because the active regions can have a large area (e.g., in a vertical plane), and the active regions are generally not etched and thus may have low defect densities and low non-radiative recombination rates. In addition, no sidewall passivation may be needed. There are no exposed mesa edges and thus there may not be associated reliability concerns. It is possible to make core-shell nanowire micro-LEDs with pitches less than about 1 (e.g., with width of nanowire about 0.5 μm). Multiple nanowire micro-LEDs may be grouped together to form a single pixel. Therefore, the pixel may still be functional even if one or more nanowire micro-LEDs in the group are not functional.

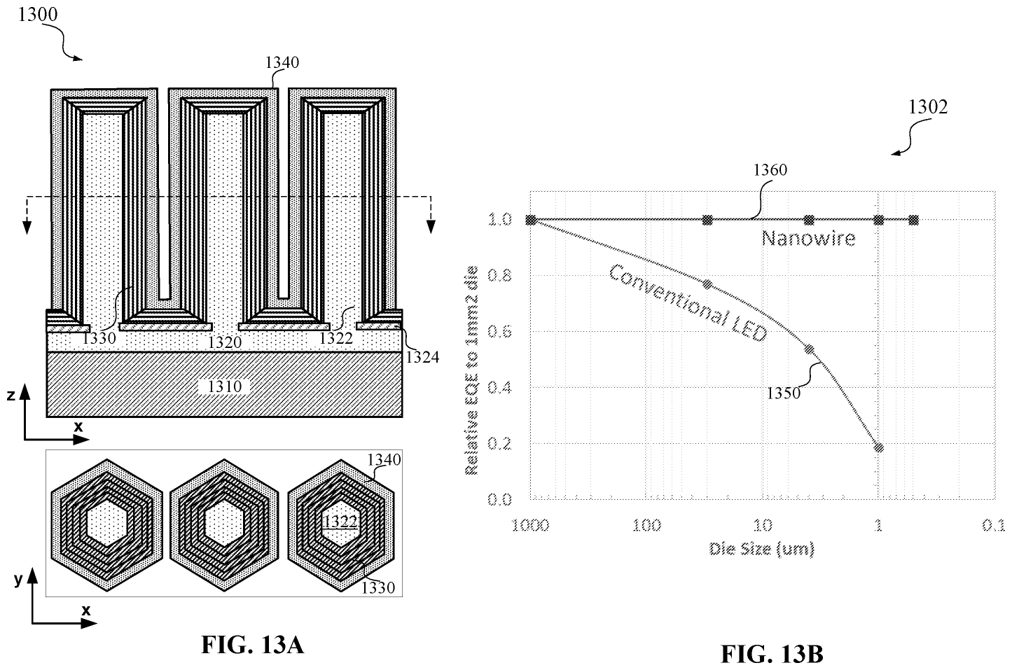

FIG. 13A illustrates an example of an array of nanowire micro-LEDs 1300. As illustrated, the array of nanowire micro-LEDs 1300 may include a substrate 1310 (e.g., including sapphire or GaAs), and a semiconductor layer 1320 grown on substrate 1310. Semiconductor layer 1320 may be undoped or doped, such as n-doped. An array of nanowire cores 1322 may be formed in or on semiconductor layer 1320. For example, nanowire cores 1322 may be grown on semiconductor layer 1320 through selective area growth (SAG) using a growth mask 1324 (e.g., including SiN). Nanowire cores 1322 may be p-doped or n-doped. Active layers 1330 may be epitaxially grown on surfaces of nanowire cores 1322. Active layers 1330 may include one or more quantum well layers and two or more quantum barrier layers to form one or more quantum wells. Another semiconductor layer 1340 may be grown on surfaces of active layers 1330. Semiconductor layer 1340 and nanowire cores 1322 may be oppositely doped, and may, in combination with active layers 1330, form core-shell nanowire micro-LEDs with horizontal p-i-n structures. The cross-section of each core-shell nanowire micro-LED may have, for example, a hexagonal shape, a circular shape, or another shape.

FIG. 13B includes a chart 1302 illustrating changes in the external quantum efficiencies of conventional micro-LEDs and core-shell nanowire micro-LEDs as the sizes of the micro-LEDs reduce. A curve 1350 show the drop in the external quantum efficiencies of conventional micro-LEDs (e.g., with etched mesa structures for individual micro-LEDs) as the sizes of the micro-LEDs reduce. A curve 1360 show the change in the external quantum efficiencies of core-shell nanowire micro-LEDs (e.g., as shown in FIG. 13A) as the size of a micro-LED pixel that includes an array of nanowire micro-LEDs reduces. Curve 1350 shows that the EQE of a conventional micro-LED with a mesa width about 1 μm may be less than 20% of the EQE of a conventional micro-LED with a mesa width about 1 mm. In contrast, curve 1360 shows that the EQE of a core-shell nanowire micro-LED with a width about 1 μm or smaller (e.g., about 0.5 μm) may be about the same as the EQE of an array of core-shell nanowire micro-LEDs (e.g., each nanowire having a diameter about 1 μm) that are connected in parallel to form a die with a size about 1 mm².

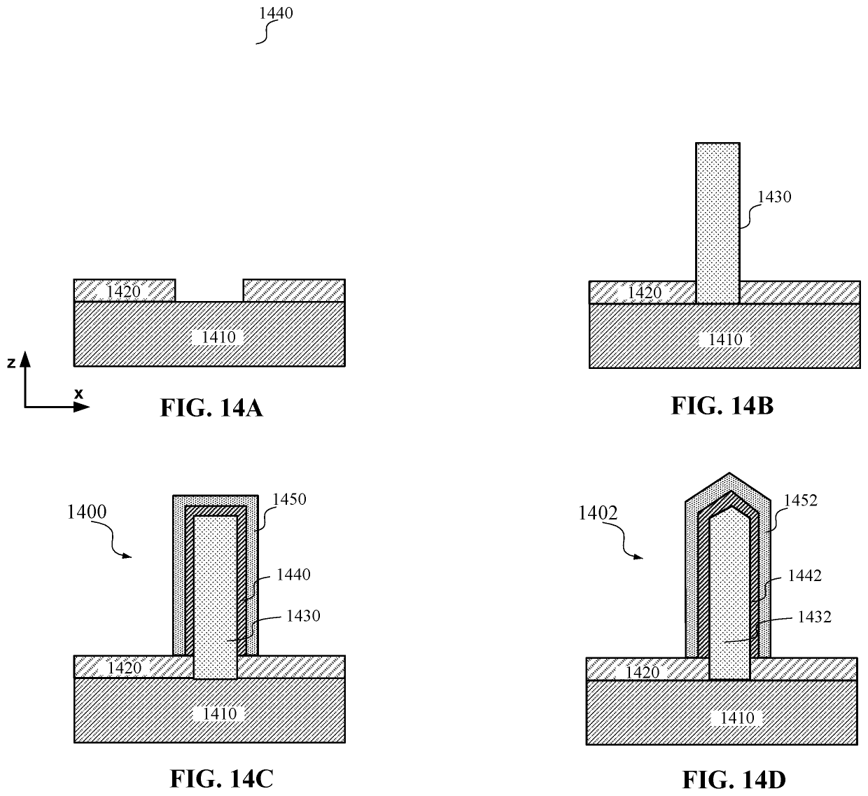

FIGS. 14A-14C illustrate an example of a method of fabricating core-shell nanowire micro-LEDs. In the illustrated example, the nanowire cores may be formed through selective area growth (SAG). FIG. 14A shows a substrate 1410 (e.g., including a GaN buffer layer) and a patterned growth mask 1420 (e.g., including SiN) formed on substrate 1410. Patterned growth mask 1420 may include apertures that define the areas for nanowire core growth. FIG. 14B shows that nanowire cores 1430 may be grown vertically on substrate 1410, through the apertures in patterned growth mask 1420. Nanowire cores 1430 may be p-doped or n-doped. FIG. 14C shows that active layers 1440 may be epitaxially grown on surfaces of nanowire cores 1430. Active layers 1440 may include one or more quantum well layers and two or more quantum barrier layers to form one or more quantum wells. Another semiconductor layer 1450 may then be grown on surfaces of active layers 1440. Semiconductor layer 1450 and nanowire cores 1430 may be oppositely doped, and may, in combination with active layers 1440, form a core-shell nanowire micro-LED 1400 with horizontal p-i-n structures.

Growing nanowire cores 1430 (e.g., n-doped cores) using SAG as described above may need a higher doping density (e.g., >1×10²⁰/cm³) in order to grow nanowire cores 1430 vertically and straightly. Due to the high doping density, nanowire cores 1430 may have a high defect density, and thus the subsequently grown active layers 1440 may have a high defect density and a low quality. In addition, the heights of the nanowire cores may vary significantly across a wafer. Furthermore, as shown in FIG. 14C, growing active layers on the cores grown by SAG may also grow parasitic active layers on the c-plane (e.g., on top of nanowire cores 1430), in addition to the active layers grown on the m-plane (e.g., sidewalls of nanowire cores 1430). Thus, core-shell nanowire micro-LED 1400 may include m-plane active layers and c-plane active layers that may emit light in different wavelength ranges.

FIG. 14D illustrates an example of a core-shell nanowire micro-LED 1402 with parasitic r-plane growth. As illustrated, growing nanowire cores vertically through patterned growth mask 1420 may form nanowire cores 1432 that may have top surfaces that may not be flat. For example, the top surfaces of nanowire cores 1432 may be parallel to r-planes of the wurtzite structure of GaN. Therefore, active layers 1442 grown on surfaces of nanowire cores 1432 may include m-plane active layers on sidewalls of nanowire cores 1432 and r-plane active layers on top surfaces of nanowire cores 1432. Similarly, semiconductor layer 1452 (e.g., including p-doped GaN) may also include portions (e.g., at the sidewalls of nanowire cores 1432) that are parallel to m-planes and portions (e.g., at the top of nanowire cores 1432) that are parallel to r-planes.

Due to the different lattice structures of the c-plane, r-plane, and m-plane semiconductor layers, the c-plane or r-plane active layers as shown in FIGS. 14C and 14D may emit light with wavelengths different from the wavelengths of the light emitted by the m-plane active layers. In addition, due to the simultaneous growth of active layers on the m-planes and c-plane and/or r-planes, the window of the growth condition may be narrow, and thus the growth condition may need to be more precisely controlled. Moreover, the active layers grown near the bottom of nanowire cores may have lower quality and thus lower quantum efficiency.

According to certain embodiments, the cores of nanowire micro-LEDs may be formed by etching an epitaxial layers using an etch mask, where the remaining etch mask may then be used as the growth mask on top of the nanowire cores during the growth of the active region, such that no parasitic c-plane or r-plane active layers may be grown on top of the nanowire cores. Since the cores may be formed by etching a uniform semiconductor layer that may be relatively low-doped, the heights of the nanowire cores may be more uniform and the quality of the nanowire cores may be better, compared with nanowire cores formed by SAG. Because the active layers may only be grown on the m-planes, the window of the growth condition can be wide. Core-shell nanowire micro-LEDs configured to emit light of different colors may be formed on a same wafer using techniques disclosed herein. Additional structures may be formed on the core-shell nanowire micro-LEDs to guide the light emitted in the active layers, such that light beams emitted from the core-shell nanowire micro-LEDs may be more directional and may be more efficiently coupled to, for example, a waveguide display.

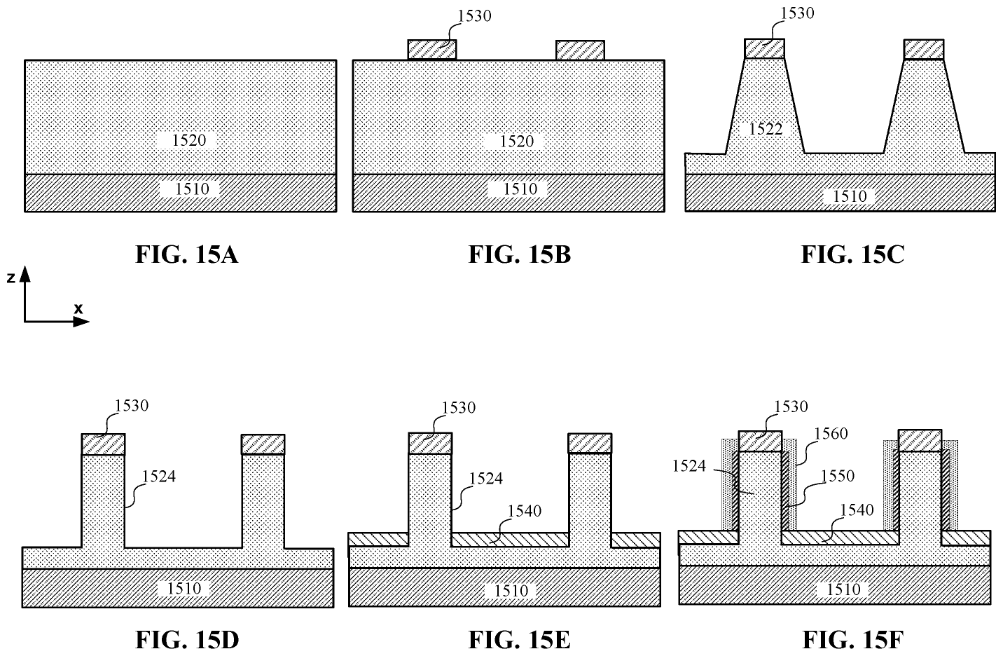

FIGS. 15A-15F illustrate an example of a method of fabricating core-shell nanowire micro-LEDs with improved performance according to certain embodiments. FIG. 15A shows a substrate 1510 (e.g., including sapphire, GaAs, or other substrates as described above) and a semiconductor layer 1520 grown on substrate 1510. Semiconductor layer 1520 may be undoped or doped, such as n-doped. In one example, semiconductor layer 1520 may include an n-doped GaN layer. FIG. 15B shows a patterned etch mask layer (e.g., including SiN) formed on semiconductor layer 1520. The patterned etch mask layer may include etch masks 1530 in regions that define the nanowire cores. Each etch mask 1530 may have, for example, a circular shape or a hexagonal shape. Each etch mask 1530 may have a width less than about 1 μm, less than about 0.5 μm, or equal to or less than about 0.2 μm. FIG. 15C shows that semiconductor layer 1520 may be dry etched using, for example, ion beams, through etch masks 1530. The dry etching using etch masks 1530 may form an array of nanostructures 1522 in semiconductor layer 1520. Nanostructures 1522 may have inwardly tilted sidewalls that may include surface damages caused by the dry etching. Etch masks 1530 may be kept after the etching. FIG. 15D shows that surfaces of nanostructures 1522 may be wet treated using, for example, potassium hydroxide (KOH) and/or tetramethyl ammonium hydroxide (TMAH), to remove surface damages and improve the quality of the sidewalls of nanostructures 1522. The wet treatment may etch nanostructures 1522 anisotropically and may form nanorods 1524 with hexagonal cross-sections. Etch masks 1530 may be kept during the wet treatment, and thus the top surfaces of nanostructure 1522 may not be etched. As such, nanorods 1524 may have the same height and good surface quality.

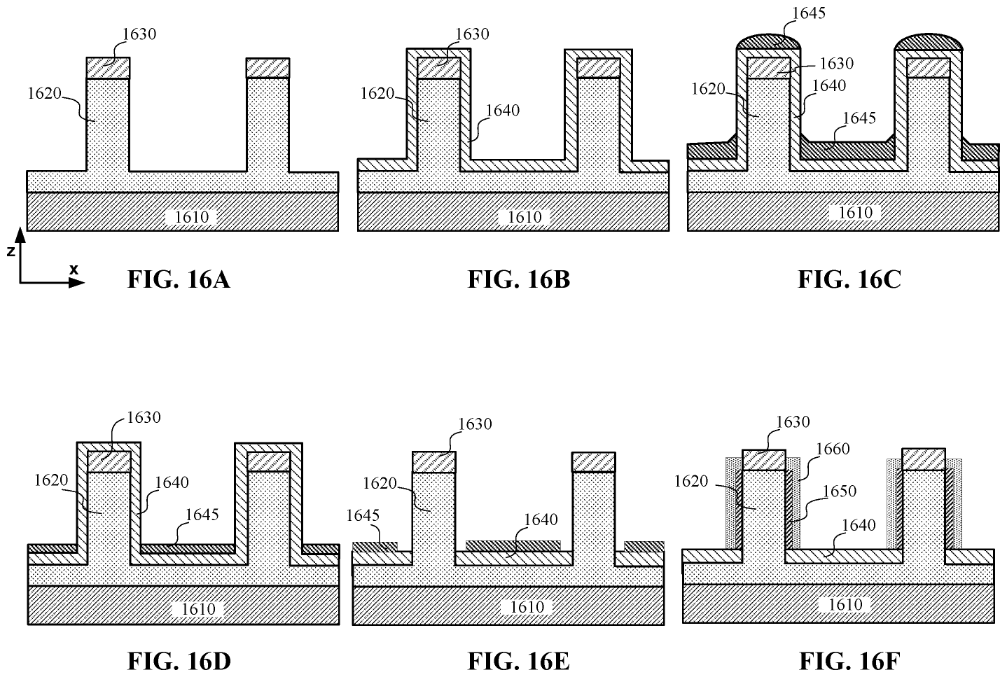

In FIG. 15E, a dielectric layer 1540 (e.g., including SiO2) may be formed on horizontal surfaces of remaining semiconductor layer 1520, such as regions between nanorods 1524. More details of the process of forming dielectric layer 1540 are described below with respect to, for example, FIGS. 16A-16E. FIG. 15F shows that active layers 1550 may be epitaxially grown on sidewall surfaces of nanorods 1524. Active layers 1550 may include one or more quantum well layers (e.g., including InGaN) and two or more quantum barrier layers (e.g., including GaN) to form one or more quantum wells. Etch masks 1530 are kept during the growth of active layers 1550, and thus active layers 1550 may only be grown on m-planes of nanorods 1524, but may not be grown on the c-plane or r-planes of nanorods 1524 due to etch masks 1530 at the top surfaces of nanorods 1524. Another semiconductor layer 1560 (e.g., p-doped GaN) may be grown on surfaces of active layers 1550. Semiconductor layer 1560 and nanorods 1524 may be oppositely doped, and may, in combination with active layers 1550 grown on the m-planes, form core-shell nanowire micro-LEDs with horizontal p-i-n structures. Etch masks 1530 may remain in the fabricated core-shell nanowire micro-LEDs. The core-shell nanowire micro-LEDs fabricated using this process may only include m-plane active layers, and may not include parasitic c-plane or r-plane active layers that may emit light in different spectral ranges. In addition, the core-shell nanowire micro-LEDs fabricated using techniques disclosed herein can have much higher EQEs. In one example, blue light-emitting core-shell nanowire micro-LEDs fabricated using techniques disclosed herein can have an EQE greater than 25%.

FIGS. 16A-16F illustrate another example of a method of fabricating nanowire micro-LEDs with improved performance according to certain embodiments. The method described in FIGS. 16A-16E may be used to form dielectric layer 1540. FIG. 16A shows examples of nanowire cores 1620 etched in a semiconductor layer that may be epitaxially grown on a substrate 1610, as described above with respect to, for example, FIGS. 15A-15D. Etch masks 1630 (e.g., including SiN) may remain on nanowire cores 1620 after the etching. As described above, in some embodiments, nanowire cores 1620 may be nanorods with hexagonal cross-sections. FIG. 16B shows that a dielectric layer 1640 (e.g., including SiO₂) may be conformally deposited on surfaces of the semiconductor layer and etch masks 1630. Dielectric layer 1640 may have a uniform thickness and may be deposited, for example, using atomic layer deposition (ALD).

FIG. 16C shows that a photoresist layer 1645 may be coated on surfaces of dielectric layer 1640, for example, by spin coating. Photoresist layer 1645 may have a higher thickness in regions between nanowire cores 1620 and low thicknesses on top and sidewalls of dielectric layer 1640 due to the spin coating. As shown in FIG. 16D, photoresist layer 1645 may be processed by directional ashing, where the photoresist may be exposed to, for example, plasma, such that the exposed portions of the photoresist may react with the plasma to generate volatile byproducts that may be removed, and thus the thickness of photoresist layer 1645 may be reduced due to the reactions and shrinkage of the photoresist. Due to the high thickness of photoresist layer 1645 in regions between nanowire cores 1620, there may be photoresist remaining in regions between nanowire cores 1620 after the photoresist on the top and sidewall surfaces of dielectric layer 1640 is completely removed by the ashing.

FIG. 16E shows that dielectric layer 1640 may be wet etched using the remaining photoresist layer 1645 as the etch mask. The wet etch may remove dielectric layer 1640 on top of etch masks 1630 and on sidewalls of nanowire cores 1620. Dielectric layer 1640 in regions between nanowire cores 1620 may remain. After the wet etching, remaining photoresist layer 1645 may be removed, and a structure including nanowire cores, etch masks on top surfaces of the nanowire cores, and a dielectric layer in regions between the nanowire cores as show in FIG. 15E may be formed.

FIG. 16F shows that, after removal of photoresist layer 1645, active layers 1650 may be epitaxially grown on sidewall surfaces of nanowire cores 1620. Active layers 1650 may include one or more quantum well layers (e.g., including InGaN) and two or more quantum barrier layers (e.g., including GaN) to form one or more quantum wells. Etch masks 1630 are kept during the growth of active layers 1650, and thus active layers 1650 may only be grown on m-planes of nanowire cores 1620, but may not be grown on the c-plane or r-planes of nanowire cores 1620 due to etch masks 1630 at the top surfaces of nanowire cores 1620. Another semiconductor layer 1660 (e.g., p-doped GaN) may be grown on surfaces of active layers 1650. Semiconductor layer 1660 and nanowire cores 1620 may be oppositely doped, and may, in combination with active layers 1650 grown on the m-planes, form core-shell nanowire micro-LEDs with horizontal p-i-n structures. Etch masks 1630 may remain in the fabricated core-shell nanowire micro-LEDs. The core-shell nanowire micro-LEDs fabricated using this process may only include m-plane active layers, and may not include parasitic c-plane or r-plane active layers that may emit light in different spectral ranges.

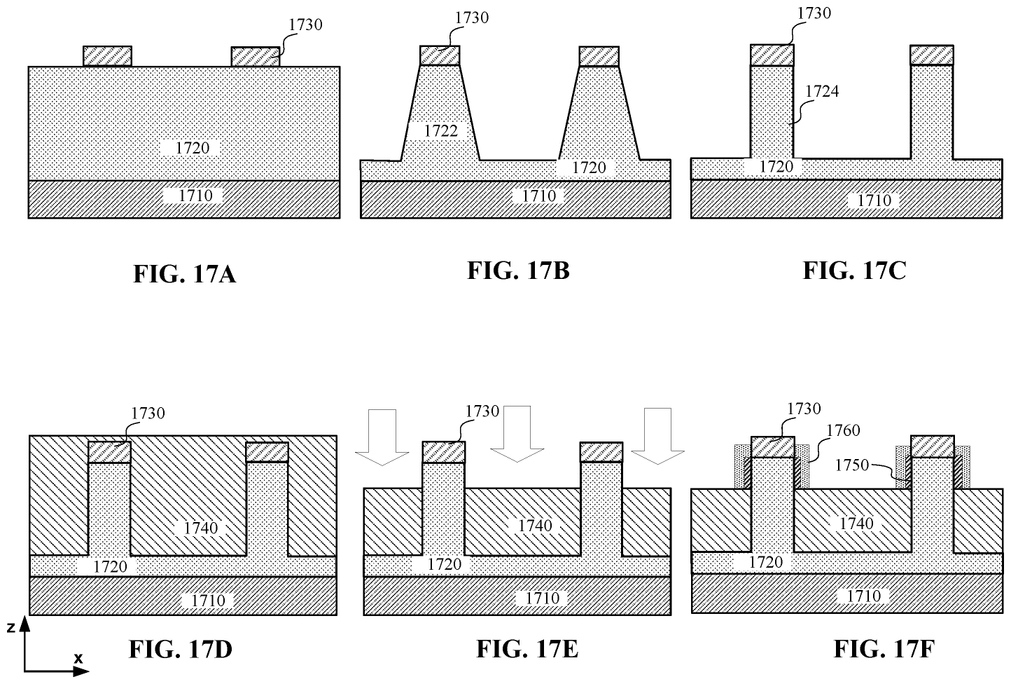

FIGS. 17A-17F illustrate yet another example of a method of fabricating nanowire micro-LEDs with improved performance according to certain embodiments. FIG. 17A shows a substrate 1710 (e.g., including sapphire, GaAs, or other substrates as described above) and a semiconductor layer 1720 grown on substrate 1710. Semiconductor layer 1720 may be undoped or doped, such as n-doped. In one example, semiconductor layer 1720 may include an n-doped GaN layer. A patterned etch mask layer (e.g., including SiN) may then be formed on semiconductor layer 1720. The patterned etch mask layer may include etch masks 1730 in regions that define the nanowire cores. Each etch mask 1730 may have, for example, a circular shape or a hexagonal shape.

FIG. 17B shows that semiconductor layer 1720 may be dry etched using, for example, ion beams, through etch masks 1730. The dry etching using etch masks 1730 may form an array of nanostructures 1722 in semiconductor layer 1720. Nanostructures 1722 may have inwardly tilted sidewalls that may include surface damages caused by the dry etching. Etch masks 1730 may be kept after the etching. FIG. 17C shows that surfaces of nanostructures 1722 may be wet treated using, for example, KOH and/or TMAH, to remove surface damages and improve the quality of the sidewalls of nanostructures 1722. The wet treatment may etch nanostructures 1722 anisotropically and may form nanorods 1724 with hexagonal cross-sections. Etch masks 1730 may be kept during the wet treatment, and thus the top surfaces of nanostructure 1722 may not be etched. As such, nanorods 1724 may have the same height and good surface quality.

In FIG. 17D, a dielectric layer 1740 (e.g., including Sift) may be deposited on the wafer. Dielectric layer 1740 may be a thick layer that may fill regions between nanorods 1724 and etch masks 1730. In some embodiments, the top surface of dielectric layer 1740 may be planarized by, for example, CMP. As shown in FIG. 17E, dielectric layer 1740 may be etched, for example, using inductively coupled plasma (ICP), to expose etch masks 1730 and a top portion of nanorods 1724, which may be a fraction (e.g., less than ½) of nanorods 1724.

FIG. 17F shows that active layers 1750 may be epitaxially grown on the exposed sidewall surfaces of nanorods 1724. Active layers 1750 may include one or more quantum well layers (e.g., including InGaN) and two or more quantum barrier layers (e.g., including GaN) to form one or more quantum wells. Etch masks 1730 are kept during the growth of active layers 1750, and thus active layers 1750 may only be grown on m-planes of the exposed sidewalls of nanorods 1724, but may not be grown on the c-plane or r-planes of nanorods 1724 due to etch masks 1730 at the top surfaces of nanorods 1724. Another semiconductor layer 1760 (e.g., p-doped GaN) may be grown on surfaces of active layers 1750. Semiconductor layer 1760 and nanorods 1724 may be oppositely doped, and may, in combination with active layers 1750 grown on the m-planes, form core-shell nanowire micro-LEDs with horizontal p-i-n structures. Etch masks 1730 may remain in the fabricated core-shell nanowire micro-LEDs. The core-shell nanowire micro-LEDs fabricated using this process may only include m-plane active layers, and may not include parasitic c-plane or r-plane active layers that may emit light in different spectral ranges. The core-shell nanowire micro-LEDs fabricated using this method may have a lower height (e.g., less than ½) than the core-shell nanowire micro-LEDs fabricated using methods described above with respect to FIGS. 15A-16F, and may have a donut shape, rather than a cylinder shape.

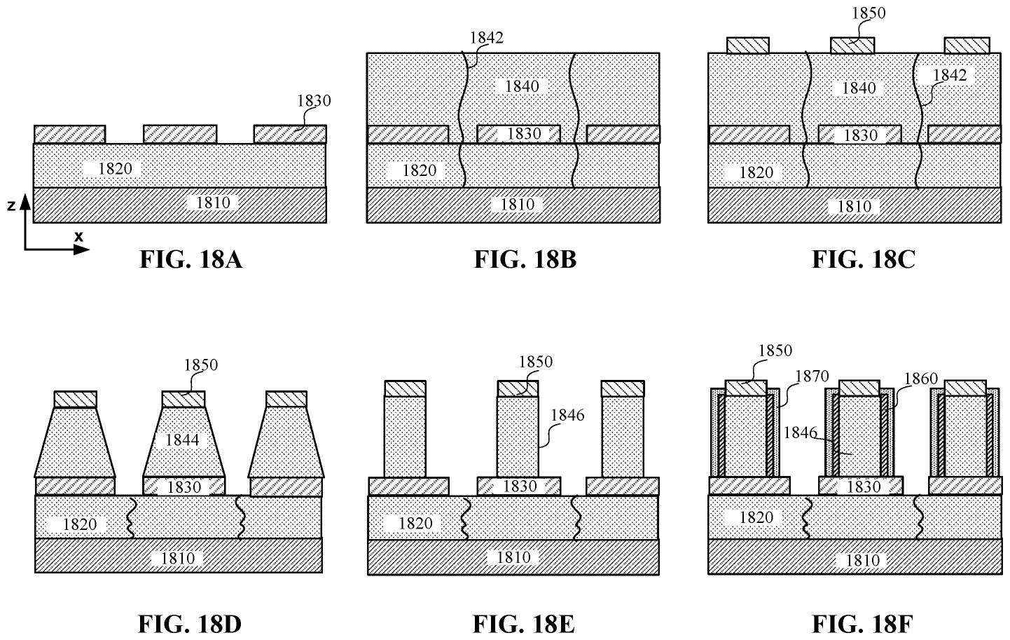

FIGS. 18A-18F illustrate another example of a method of fabricating nanowire micro-LEDs with improved performance according to certain embodiments. FIG. 18A shows a substrate 1810 (e.g., including sapphire, GaAs, or other substrates as described above) and a semiconductor layer 1820 grown on substrate 1810. Semiconductor layer 1820 may be undoped or doped, such as n-doped, and may be used as a buffer layer. In one example, semiconductor layer 1820 may include an n-doped GaN layer. A patterned growth mask 1830 (e.g., including SiN or SiO₂) may be formed on semiconductor layer 1820. Patterned growth mask 1830 may include apertures for epitaxial lateral overgrowth (ELOG).

FIG. 18B shows that a semiconductor layer 1840 (e.g., including GaN) may be grown on semiconductor layer 1820, through the apertures in patterned growth mask 1830. Semiconductor layer 1840 may be p-doped or n-doped. As illustrated in the example, there may be threading dislocations 1842 in semiconductor layer 1840 due to threading dislocations in substrate 1810 or semiconductor layer 1820. However, in regions of semiconductor layer 1840 above patterned growth mask 1830, the threading dislocations may be masked by patterned growth mask 1830.

FIG. 18C shows a patterned etch mask layer (e.g., including SiN) formed on semiconductor layer 1840. The patterned etch mask layer may include etch masks 1850 on regions of semiconductor layer 1840 that are on top of patterned growth mask 1830 and thus have no threading dislocations. Each etch mask 1850 may have, for example, a circular shape or a hexagonal shape. FIG. 18D shows that semiconductor layer 1840 may be dry etched using, for example, ion beams, through etch masks 1850. The dry etching using etch masks 1850 may remove regions of semiconductor layer 1840 that may include threading dislocations 1842 to form an array of nanostructures 1844 in semiconductor layer 1840. Nanostructures 1844 may be formed on top of patterned growth mask 1830, and thus may not include threading dislocations due to the masking by patterned growth mask 1830. Nanostructures 1844 may have inwardly tilted sidewalls that may include surface damages caused by the dry etching. The dry etching may etch through semiconductor layer 1840 to expose at least a portion of patterned growth mask 1830. Etch masks 1850 may be kept after the etching. FIG. 18E shows that surfaces of nanostructures 1844 may be wet treated using, for example, KOH and/or TMAH, to remove surface damages and improve the quality of the sidewalls of nanostructures 1844. The wet treatment may etch nanostructures 1844 anisotropically and may form nanorods 1846 with hexagonal cross-sections. Etch masks 1850 may be kept during the wet treatment, and thus the top surfaces of nanostructures 1844 may not be etched. As such, nanorods 1846 may have the same or similar heights and good surface quality.

FIG. 18F shows that active layers 1860 may be epitaxially grown on sidewall surfaces of nanorods 1846. Active layers 1860 may include one or more quantum well layers (e.g., including InGaN) and two or more quantum barrier layers (e.g., including GaN) to form one or more quantum wells. Etch masks 1850 are kept during the growth of active layers 1860, and thus active layers 1860 may only be grown on m-planes of nanorods 1846, but may not be grown on the c-plane or r-planes of nanorods 1846 due to etch masks 1850 at the top surfaces of nanorods 1846. Another semiconductor layer 1870 (e.g., p-doped GaN) may be grown on surfaces of active layers 1860. Semiconductor layer 1870 and nanorods 1846 may be oppositely doped, and may, in combination with active layers 1860 grown on the m-planes, form core-shell nanowire micro-LEDs with horizontal p-i-n structures. Etch masks 1850 may remain in the fabricated core-shell nanowire micro-LEDs. The structure shown in FIG. 18F may be processed from the side of etch masks 1850 to form a common electrode (e.g., a common anode) that is electrically connected to semiconductor layer 1870, and may be processed from the side of semiconductor layer 1820 to from individual electrodes (e.g., cathodes) that pass through semiconductor layer 1820 and patterned growth masks 1830 to make electrical contacts with nanorods 1846. The core-shell nanowire micro-LEDs fabricated using this process may only include m-plane active layers, and may not include parasitic c-plane or r-plane active layers that may emit light in different spectral ranges. In this process, a dielectric layer as shown in FIGS. 15E, 16B-16F, and 17D-17F may not need to be formed.

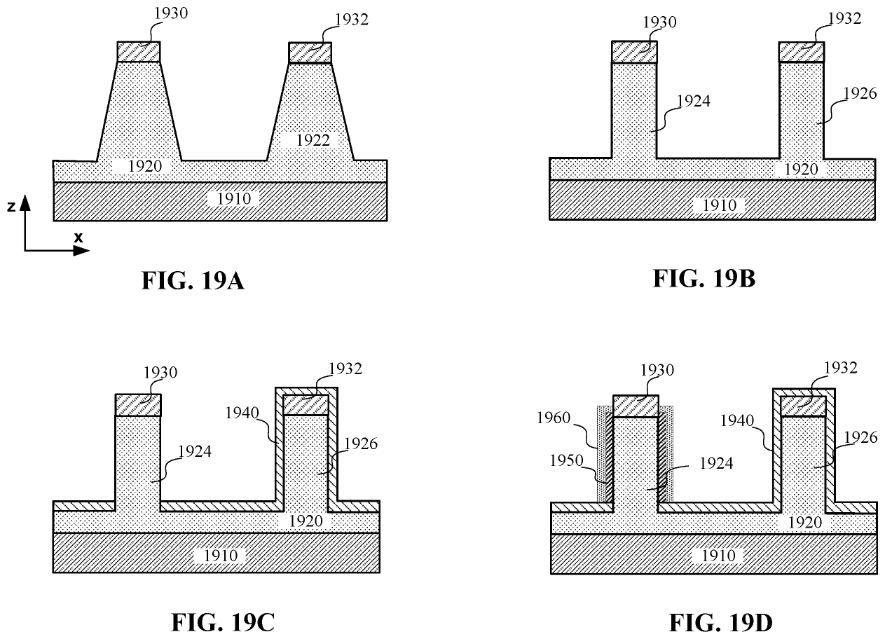

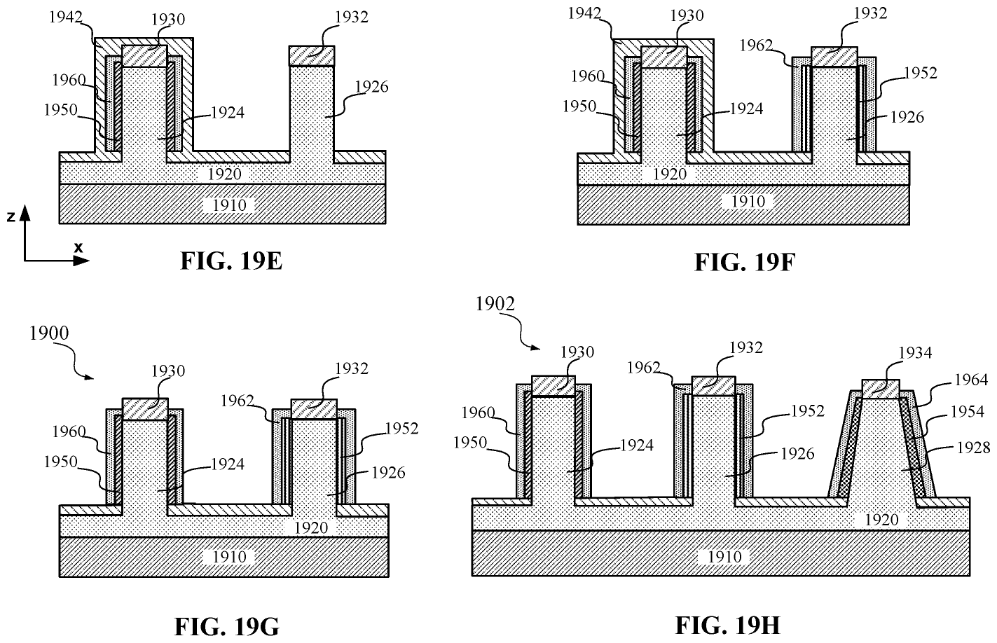

FIGS. 19A-19H illustrate an example of a method of fabricating multi-color nanowire micro-LEDs with improved performance according to certain embodiments. FIG. 19A shows a substrate 1910 (e.g., including sapphire, GaAs, or other substrates as described above) and a semiconductor layer 1920 grown on substrate 1910. Semiconductor layer 1920 may be undoped or doped, such as n-doped. In one example, semiconductor layer 1920 may include an n-doped GaN layer. Semiconductor layer 1920 may be etched using a patterned etch mask layer (e.g., including SiN) formed on semiconductor layer 1920 to form nanostructures 1922, as described above with respect to, for example, FIGS. 15B-15C and 17A-17B. The patterned etch mask layer may include etch masks 1930 and 1932 in regions that define the nanowire cores. Each etch mask 1930 or 1932 may have, for example, a circular shape or a hexagonal shape. Semiconductor layer 1920 may be dry etched using, for example, ion beams, through etch masks 1930 and 1932. The dry etching using etch masks 1930 and 1932 may form an array of nanostructures 1922 in semiconductor layer 1920. Nanostructures 1922 may have inwardly tilted sidewalls that may include surface damages caused by the dry etching. Etch masks 1930 and 1932 may be kept after the etching of semiconductor layer 1920.

FIG. 19B shows that surfaces of nanostructures 1922 may be wet treated using, for example, KOH and/or TMAH, to remove surface damages and improve the quality of the sidewalls of nanostructures 1922. The wet treatment may etch nanostructures 1922 anisotropically and may form nanorods 1924 and 1926 with hexagonal cross-sections. Etch masks 1930 and 1932 may be kept during the wet treatment, and thus the top surfaces of nanostructures 1922 may not be etched. As such, nanorods 1924 and 1926 may have the same heights and good surface quality.

FIG. 19C shows that a dielectric layer 1940 may be formed on top of etch masks 1932, sidewalls of nanorods 1926, and regions between nanorods 1924 and 1926, for example, using techniques described above with respect to FIGS. 16B-16E, where regions surrounding nanorods 1926 may be masked during the wet etching of dielectric layer 1940 surrounding nanorods 1924. Thus, nanorods 1926 may be surrounded by dielectric layer 1940, while sidewalls of nanorods 1924 may be exposed.

As shown in FIG. 19D, active layers 1950 may be epitaxially grown on sidewall surfaces of nanorods 1924. Active layers 1950 may include one or more quantum well layers (e.g., including InGaN) and two or more quantum barrier layers (e.g., including GaN) to form one or more quantum wells. The quantum well layers may be configured to emit, for example, blue light, due to the incorporation of an appropriate amount of indium or other elements in the quantum well layers. Etch masks 1930 are kept during the growth of active layers 1950, and thus active layers 1950 may only be grown on m-planes of nanorods 1924, but may not be grown on the c-plane or r-planes of nanorods 1924. Active layer 1950 may not be grown on dielectric layer 1940 due to, for example, the large lattice structure mismatch. Another semiconductor layer 1960 (e.g., p-doped GaN) may be grown on surfaces of active layers 1950. Semiconductor layer 1960 and nanorods 1924 may be oppositely doped, and may, in combination with active layers 1950 grown on the m-planes, form core-shell nanowire micro-LEDs with horizontal p-i-n structures and configured to emit, for example, blue light. Etch masks 1930 may remain in the fabricated core-shell nanowire micro-LEDs. The core-shell nanowire micro-LEDs may only include m-plane active layers, and may not include parasitic c-plane or r-plane active layers that may emit light in different spectral ranges.

FIG. 19E shows that a dielectric layer 1942 may be formed to surround etch masks 1930 and the core-shell nanowire micro-LEDs formed using nanorods 1924. Dielectric layer 1942 may be formed using, for example, techniques described above with respect to FIGS. 16B-16E, where regions surrounding nanorods 1924 may be masked during the wet etching of dielectric layer 1942 surrounding nanorods 1926. Thus, nanorods 1926 may be exposed, and the core-shell nanowire micro-LEDs formed using nanorods 1924 may be protected by dielectric layer 1942.

FIG. 19F shows that active layers 1952 may be epitaxially grown on sidewall surfaces of nanorods 1926. Active layers 1952 may include one or more quantum well layers (e.g., including InGaN) and two or more quantum barrier layers (e.g., including GaN) to form one or more quantum wells. The quantum well layers may be configured to emit, for example, green light, due to the incorporation of an appropriate amount of indium or other elements in the quantum well layers. Etch masks 1932 are kept during the growth of active layers 1952, and thus active layers 1952 may only be grown on m-planes of nanorods 1926, but may not be grown on the c-plane or r-planes of nanorods 1926. Active layer 1952 may not be grown on dielectric layer 1942 due to, for example, the large lattice structure mismatch. Another semiconductor layer 1962 (e.g., p-doped GaN) may be grown on surfaces of active layers 1952. Semiconductor layer 1962 and nanorods 1926 may be oppositely doped, and may, in combination with active layers 1952 grown on the m-planes, form core-shell nanowire micro-LEDs with horizontal p-i-n structures and configured to emit, for example, green light. Etch masks 1932 may remain in the fabricated core-shell nanowire micro-LEDs. The core-shell nanowire micro-LEDs fabricated using nanorods 1926 may only include m-plane active layers, and may not include parasitic c-plane or r-plane active layers that may emit light in different spectral ranges.

FIG. 19G shows a device 1900 with both core-shell nanowire micro-LEDs configured to emit blue light and core-shell nanowire micro-LEDs configured to emit green light, after dielectric layer 1942 is removed. FIG. 1911 shows a device 1902 including core-shell nanowire micro-LEDs configured to emit blue light and core-shell nanowire micro-LEDs configured to emit green light as in device 1900, and core-shell nanowire micro-LEDs configured to emit red light. The core-shell nanowire micro-LEDs configured to emit red light may include nanorods 1928, active layers 1954 grown on sidewalls of nanorods 1928, and a semiconductor layer 1964 (e.g., p-doped GaN layer) grown on active layers 1954. Nanorods 1928 may have a truncated pyramid shape that may include sidewalls on semipolar planes and may be formed by etching semiconductor layer 1920 using etch masks 1934, without performing wet treatment using KOH/TMAH. Therefore, active layers 1954 may be on semipolar planes and may be grown to emit red light by selecting the composition of the quantum well layers. Semiconductor layer 1964 and nanorods 1928 may be oppositely doped, and may, in combination with active layers 1954, form core-shell nanowire micro-LEDs configured to emit red light. In some embodiments, core-shell nanowire micro-LEDs configured to emit green light may also be formed by growing active layers on semipolar planes. In this way, multi-color core-shell nanowire micro-LEDs may be fabricated on a same substrate 1910.

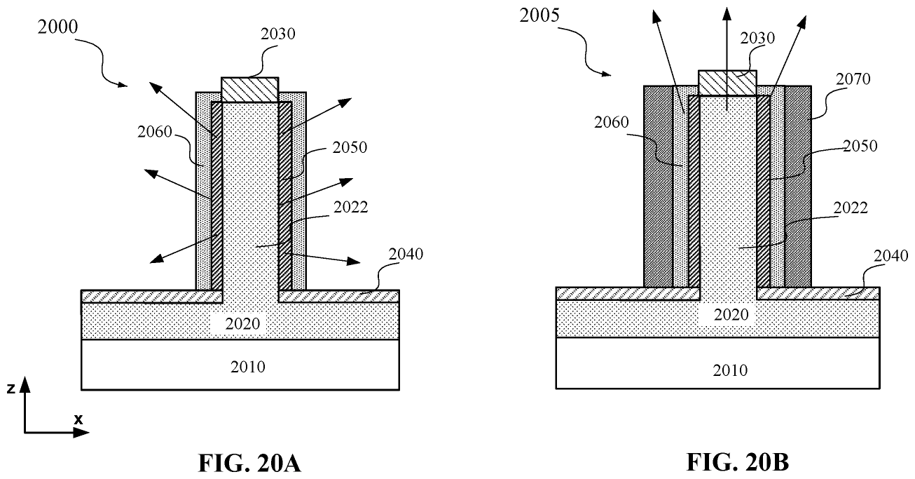

FIG. 20A illustrates light emission by an example of a core-shell nanowire micro-LED 2000 according to certain embodiments. Core-shell nanowire micro-LED 2000 may be fabricated using any method described above. In the illustrated example, core-shell nanowire micro-LED 2000 may include a substrate 2010, a semiconductor layer 2020 (e.g., an n-doped GaN layer), and a nanowire core 2022 formed in or on semiconductor layer 2020 using an etch mask 2030. A dielectric layer 2040 may be formed in regions between nanowire cores 2022 of adjacent core- shell nanowire micro-LEDs to prevent growth of epitaxial layers on horizontal surfaces of semiconductor layer 2020. Active layers 2050 and a semiconductor layer 2060 may be grown on sidewalls of nanowire core 2022, while etch mask 2030 remains on top of nanowire cores 2022. Thus, active layers 2050 may only be grown on sidewall of nanowire core 2022. Light may be emitted by active layers 2050 when core-shell nanowire micro-LED 2000 is forwardly biased. As illustrated, the light may be emitted into many directions.

FIG. 20B illustrates light emission by an example of a core-shell nanowire micro-LED 2005 including a waveguide structure according to certain embodiments. Core-shell nanowire micro-LED 2005 may be similar to core-shell nanowire micro-LED 2000, but may also include a layer of a high refractive index material 2070 formed on sidewalls of semiconductor layer 2060. High refractive index material 2070 may include, for example, TiO₂, high refractive index SiN, or regrown GaN. Thus, the layer of high refractive index material 2070 may form a cladding layer of the waveguide structure, where active layers 2050 may be in the core of the waveguide structure. As such, light emitted in active layers 2050 may be confined and guided by the layer of high refractive index material 2070, and may exit core-shell nanowire micro-LED 2005 only from the top of core-shell nanowire micro-LED 2005 as shown in FIG. 20B. Because only light with certain incidence angles may be guided by the waveguide structure, the emitted light beam may be more directional (e.g., having a small emission cone) and thus may be more efficiently coupled into a waveguide display.

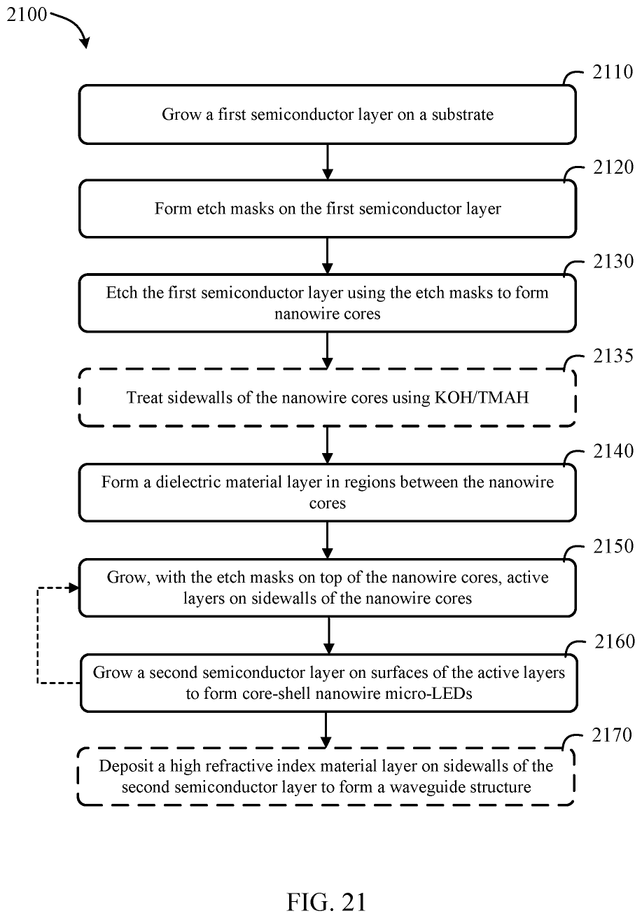

FIG. 21 includes a flowchart 2100 illustrating an example of a process of fabricating core-shell nanowire micro-LEDs according to certain embodiments. It is noted that the operations illustrated in FIG. 21 provide particular processes for fabricating core-shell nanowire micro-LEDs. Other sequences of operations can also be performed according to alternative embodiments. For example, alternative embodiments may perform the operations in a different order. Moreover, the individual operations illustrated in FIG. 21 can include multiple sub-operations that can be performed in various sequences as appropriate for the individual operation. Furthermore, some operations can be added or removed depending on the particular applications. In some implementations, two or more operations may be performed in parallel. One of ordinary skill in the art would recognize many variations, modifications, and alternatives.

Operations in block 2110 may include growing a first semiconductor layer on a substrate. The substrate may include, for example, a GaAs wafer, a sapphire wafer, or a silicon wafer. In some embodiments, the substrate may also include a buffer layer, which may be doped or undoped. The first semiconductor layer may be epitaxially grown on the substrate (or the buffer layer). In some embodiments, the first semiconductor layer may be grown on the substrate (or the buffer layer) through a patterned growth mask using epitaxial lateral overgrowth techniques as described above with respect to, for example, FIGS. 18A-18B. The first semiconductor layer may include p-doped or n-doped GaN, GaP, GaInP, or other III-N or III-P semiconductor materials. The first semiconductor layer may be lightly or moderately doped with a doping density, for example, below about 1×10²⁰ cm⁻³. In some embodiments, the first semiconductor layer may be planarized using, for example, CMP.

Operations in block 2120 may include forming etch masks on the first semiconductor layer, as described above with respect to, for example, FIG. 15B, 17A, or 18C. Forming the etch masks on the first semiconductor later may include depositing an etch mask layer on the first semiconductor layer, depositing a photoresist layer on the etch mask layer, exposing the photoresist layer to light (e.g., UV light) through a photomask, developing the photoresist layer, and etching the etch mask layer using the developed photoresist layer to transfer the pattern in the photoresist layer to the etch mask layer. In some embodiments, the etch mask layer may include SiN. The etch masks formed in the etch mask layer may include an array of etch masks that may define centers of the core-shell nanowire micro-LEDs to be fabricated. The pitch of the array of etch masks may be the same as the pitch of the core-shell nanowire micro-LEDs, such as less than about 2 μm or less than about 1 μm. The size of each etch mask of the array of etch masks may be equal to the desired size of a nanowire core, such as with a width less than about 1 μm, less than about 0.5 μm, or equal to or less than about 0.2 μm. Each etch mask may have, for example, a circular shape or a hexagonal shape.

Operations in block 2130 may include etching the first semiconductor layer using the etch masks to form nanowire cores in the first semiconductor layer, as described above with respect to, for example, FIGS. 15C, 17B, 18D, and 19A. The etching process may include a dry etching process using, for example, ion beams. The etching may remove materials in areas not covered by the etch masks and form an array of nanowire cores under the array of etch masks. Each nanowire core may be a mesa structure with vertical or tilted sidewalls, which may be on nonpolar planes (e.g., m-planes) or semipolar planes of the first semiconductor layer. The array of nanowire cores may have the same height since they are etched in the first semiconductor layer that may have been planarized using, for example, CMP. The etch masks may be kept during subsequent processes and may be included in the final core-shell nanowire micro-LEDs.

Optional operations in block 2135 may include treating the sidewalls of the nanowire cores using KOH/TMAH to remove surface damages and other defects near the etched sidewalls of the nanowire cores, as described above with respect to, for example, FIGS. 15D, 17C, 18E, and 19B. In some embodiments, the wet treatment using KOH and/or TMAH may etch the nanowire cores such that each nanowire core may have vertical sidewalls and may have a hexagonal shaped horizonal cross-section. Thus, each sidewalls of the six sidewalls of each nanowire core may be on an m-plane.

Operations in block 2140 may include forming a dielectric material layer (e.g., including SiO₂) in regions between the nanowire cores, as described above with respect to, for example, FIG. 15E or 17E. The dielectric material layer in regions between the nanowire cores may be used as the epitaxial growth mask. In some embodiments, the dielectric material layer may be formed in regions between the nanowire cores by conformally depositing (e.g., using ALD) a layer of a dielectric material on exposed surfaces of the first semiconductor layer and the etch masks, spin-coating a photoresist layer on the layer of the dielectric material, ashing the photoresist layer to leave photoresist only in the regions between the nanowire cores, and etching, using the remaining photoresist in the regions between the nanowire cores as an etch mask, the layer of the dielectric material to remove the dielectric material above the top surfaces of the nanowire cores and the dielectric material on sidewalls of the nanowire cores, as described above with respect to, for example, FIGS. 16B-16E. In some embodiments, the dielectric material layer may be formed in the regions between the nanowire cores by depositing a layer of a dielectric material to fill the regions between the nanowire cores, and etching the layer of the dielectric material using the etch masks on top of the nanowire cores, as described above with respect to, for example, FIGS. 17D and 17E. Thus, the dielectric material layer may physically contact and surround sidewalls of a bottom portion of each nanowire core. In some embodiments, the thickness of the dielectric material layer may be greater than a half of the height of each nanowire core.

Operations in block 2150 may include growing, with the etch masks on top of the nanowire cores, active layers on sidewalls of the nanowire cores, and operations in block 2160 may include growing a second semiconductor layer on surfaces of the active layers to form core-shell nanowire micro-LEDs, as described above with respect to, for example, FIGS. 15F, 16F, 17F, 18F, 19D, 19F, and 19H. As described above, the sidewalls of the nanowire cores may be in nonpolar planes (e.g., m-planes) or semipolar planes. Thus, the active layers may be epitaxially grown on the m-planes or semipolar planes. Because the etch masks at the top of the nanowire cores and the dielectric material layer at regions between the nanowire cores, the active layers may only be grown on sidewalls of the nanowire cores. The active layers may include one or more quantum well layers and two or more quantum barrier layers that form one or more quantum wells. The quantum wells may be configured to emit visible light, such as red, green, and/or blue light. The second semiconductor layer may be oppositely doped with respect to the nanowire cores (the first semiconductor layer). Thus, the nanowire cores, the active layers, and the second semiconductor layer may form horizontal p-i-n structures for core-shell nanowire micro-LEDs.

In some embodiments, core-shell nanowire micro-LEDs configured to emit visible light of different colors may be sequentially formed on the same substrate. For example, as shown in FIGS. 19C-19H, a first mask layer may be applied on a first set of nanowire cores of the nanowire cores, first active layers may be grown on sidewalls (e.g., m-planes or semipolar planes) of a second set of nanowire cores of the nanowire cores, and the second semiconductor layer may then be grown on surfaces of the first active layers, where the first active layers may be configured to emit light in a first wavelength range (e.g., blue light). Afterwards, the first mask layer may be removed, a second mask layer may be applied on the surfaces of the second semiconductor layer grown on the first active layers, second active layers may be grown on sidewalls (e.g., m-planes or semipolar planes) of the first set of nanowire cores, and then the second semiconductor layer may be grown on surfaces of the second active layers, where the second active layers may be configured to emit light in a second wavelength range (e.g., green light). Core-shell nanowire micro-LEDs configured to emit light in a third wavelength range (e.g., red light) may be made by covering the core-shell nanowire micro-LEDs configured to emit light in the first and second wavelength ranges, and growing third active layers and the second semiconductor layer on sidewalls (e.g., m-planes or semipolar planes) of a third set of nanowire cores, where the composition and orientation of the third active layers may be selected such that the third active layers may emit light in the third wavelength range when forward biased.

Optional operations in block 2170 may include depositing a high refractive index material layer on sidewalls of the second semiconductor layer to form a waveguide structure, as described above with respect to, for example, FIG. 20B. The high refractive index material layer may have a refractive index greater than the refractive index of the second semiconductor layer and may horizontally surround the second semiconductor layer of the core-shell nanowire micro-LEDs. Therefore, light emitted in the active layers may be confined and guided by the high refractive index material layer, and may only exit the core-shell nanowire micro-LEDs from the top of the core-shell nanowire micro-LEDs. Because only light with certain incidence angles may be guided by the waveguide structure, the emitted light beam may be more directional (e.g., having a small emission cone) and thus may be more efficiently coupled into a waveguide display.

Embodiments disclosed herein may be used to implement components of an artificial reality system or may be implemented in conjunction with an artificial reality system. Artificial reality is a form of reality that has been adjusted in some manner before presentation to a user, which may include, for example, a virtual reality, an augmented reality, a mixed reality, a hybrid reality, or some combination and/or derivatives thereof. Artificial reality content may include completely generated content or generated content combined with captured (e.g., real-world) content. The artificial reality content may include video, audio, haptic feedback, or some combination thereof, and any of which may be presented in a single channel or in multiple channels (such as stereo video that produces a three-dimensional effect to the viewer). Additionally, in some embodiments, artificial reality may also be associated with applications, products, accessories, services, or some combination thereof, that are used to, for example, create content in an artificial reality and/or are otherwise used in (e.g., perform activities in) an artificial reality. The artificial reality system that provides the artificial reality content may be implemented on various platforms, including an HMD connected to a host computer system, a standalone HMD, a mobile device or computing system, or any other hardware platform capable of providing artificial reality content to one or more viewers.

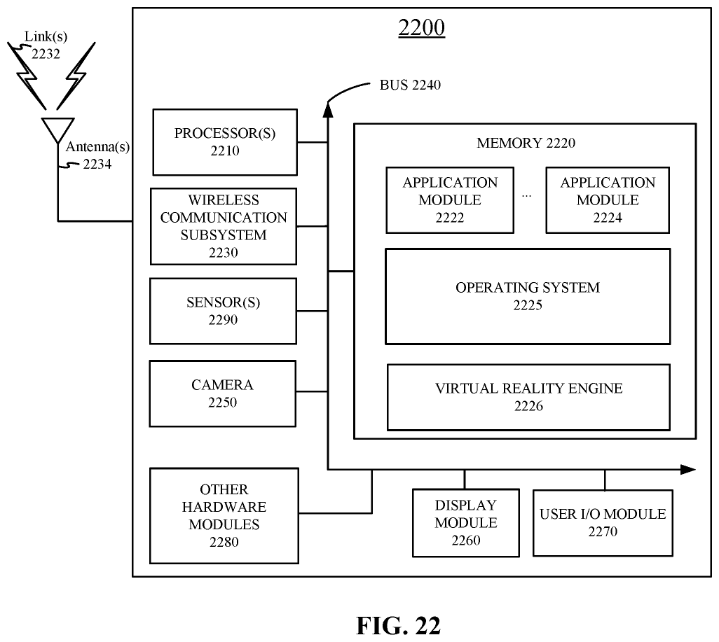

FIG. 22 is a simplified block diagram of an example electronic system 2200 of an example near-eye display (e.g., HMD device) for implementing some of the examples disclosed herein. Electronic system 2200 may be used as the electronic system of an HMD device or other near-eye displays described above. In this example, electronic system 2200 may include one or more processor(s) 2210 and a memory 2220. Processor(s) 2210 may be configured to execute instructions for performing operations at a number of components, and can be, for example, a general-purpose processor or microprocessor suitable for implementation within a portable electronic device. Processor(s) 2210 may be communicatively coupled with a plurality of components within electronic system 2200. To realize this communicative coupling, processor(s) 2210 may communicate with the other illustrated components across a bus 2240. Bus 2240 may be any subsystem adapted to transfer data within electronic system 2200. Bus 2240 may include a plurality of computer buses and additional circuitry to transfer data.

Memory 2220 may be coupled to processor(s) 2210. In some embodiments, memory 2220 may offer both short-term and long-term storage and may be divided into several units. Memory 2220 may be volatile, such as static random access memory (SRAM) and/or dynamic random access memory (DRAM) and/or non-volatile, such as read-only memory (ROM), flash memory, and the like. Furthermore, memory 2220 may include removable storage devices, such as secure digital (SD) cards. Memory 2220 may provide storage of computer-readable instructions, data structures, program modules, and other data for electronic system 2200.

In some embodiments, memory 2220 may store a plurality of application modules 2222 through 2224, which may include any number of applications. Examples of applications may include gaming applications, conferencing applications, video playback applications, or other suitable applications. The applications may include a depth sensing function or eye tracking function. Application modules 2222-2224 may include particular instructions to be executed by processor(s) 2210. In some embodiments, certain applications or parts of application modules 2222-2224 may be executable by other hardware modules 2280. In certain embodiments, memory 2220 may additionally include secure memory, which may include additional security controls to prevent copying or other unauthorized access to secure information.

In some embodiments, memory 2220 may include an operating system 2225 loaded therein. Operating system 2225 may be operable to initiate the execution of the instructions provided by application modules 2222-2224 and/or manage other hardware modules 2280 as well as interfaces with a wireless communication subsystem 2230 which may include one or more wireless transceivers. Operating system 2225 may be adapted to perform other operations across the components of electronic system 2200 including threading, resource management, data storage control and other similar functionality.

Wireless communication subsystem 2230 may include, for example, an infrared communication device, a wireless communication device and/or chipset (such as a Bluetooth® device, an IEEE 802.11 device, a Wi-Fi device, a WiMax device, cellular communication facilities, etc.), and/or similar communication interfaces. Electronic system 2200 may include one or more antennas 2234 for wireless communication as part of wireless communication subsystem 2230 or as a separate component coupled to any portion of the system. Depending on desired functionality, wireless communication subsystem 2230 may include separate transceivers to communicate with base transceiver stations and other wireless devices and access points, which may include communicating with different data networks and/or network types, such as wireless wide-area networks (WWANs), wireless local area networks (WLANs), or wireless personal area networks (WPANs). A WWAN may be, for example, a WiMax (IEEE 802.16) network. A WLAN may be, for example, an IEEE 802.11x network. A WPAN may be, for example, a Bluetooth network, an IEEE 802.15x, or some other types of network. The techniques described herein may also be used for any combination of WWAN, WLAN, and/or WPAN. Wireless communications subsystem 2230 may permit data to be exchanged with a network, other computer systems, and/or any other devices described herein. Wireless communication subsystem 2230 may include a means for transmitting or receiving data, such as identifiers of HMD devices, position data, a geographic map, a heat map, photos, or videos, using antenna(s) 2234 and wireless link(s) 2232.

Embodiments of electronic system 2200 may also include one or more sensors 2290. Sensor(s) 2290 may include, for example, an image sensor, an accelerometer, a pressure sensor, a temperature sensor, a proximity sensor, a magnetometer, a gyroscope, an inertial sensor (e.g., a module that combines an accelerometer and a gyroscope), an ambient light sensor, or any other similar module operable to provide sensory output and/or receive sensory input, such as a depth sensor or a position sensor.

Electronic system 2200 may include a display module 2260. Display module 2260 may be a near-eye display, and may graphically present information, such as images, videos, and various instructions, from electronic system 2200 to a user. Such information may be derived from one or more application modules 2222-2224, virtual reality engine 2226, one or more other hardware modules 2280, a combination thereof, or any other suitable means for resolving graphical content for the user (e.g., by operating system 2225). Display module 2260 may use LCD technology, LED technology (including, for example, OLED, ILED, μ-LED, AMOLED, TOLED, etc.), light emitting polymer display (LPD) technology, or some other display technology.

Electronic system 2200 may include a user input/output module 2270. User input/output module 2270 may allow a user to send action requests to electronic system 2200. An action request may be a request to perform a particular action. For example, an action request may be to start or end an application or to perform a particular action within the application. User input/output module 2270 may include one or more input devices. Example input devices may include a touchscreen, a touch pad, microphone(s), button(s), dial(s), switch(es), a keyboard, a mouse, a game controller, or any other suitable device for receiving action requests and communicating the received action requests to electronic system 2200. In some embodiments, user input/output module 2270 may provide haptic feedback to the user in accordance with instructions received from electronic system 2200. For example, the haptic feedback may be provided when an action request is received or has been performed.

Electronic system 2200 may include a camera 2250 that may be used to take photos or videos of a user, for example, for tracking the user's eye position. Camera 2250 may also be used to take photos or videos of the environment, for example, for VR, AR, or MR applications. Camera 2250 may include, for example, a complementary metal-oxide-semiconductor (CMOS) image sensor with a few millions or tens of millions of pixels. In some implementations, camera 2250 may include two or more cameras that may be used to capture 3-D images.

In some embodiments, electronic system 2200 may include a plurality of other hardware modules 2280. Each of other hardware modules 2280 may be a physical module within electronic system 2200. While each of other hardware modules 2280 may be permanently configured as a structure, some of other hardware modules 2280 may be temporarily configured to perform specific functions or temporarily activated. Examples of other hardware modules 2280 may include, for example, an audio output and/or input module (e.g., a microphone or speaker), a near field communication (NFC) module, a rechargeable battery, a battery management system, a wired/wireless battery charging system, etc. In some embodiments, one or more functions of other hardware modules 2280 may be implemented in software.

In some embodiments, memory 2220 of electronic system 2200 may also store a virtual reality engine 2226. Virtual reality engine 2226 may execute applications within electronic system 2200 and receive position information, acceleration information, velocity information, predicted future positions, or any combination thereof of the HMD device from the various sensors. In some embodiments, the information received by virtual reality engine 2226 may be used for producing a signal (e.g., display instructions) to display module 2260. For example, if the received information indicates that the user has looked to the left, virtual reality engine 2226 may generate content for the HMD device that mirrors the user's movement in a virtual environment. Additionally, virtual reality engine 2226 may perform an action within an application in response to an action request received from user input/output module 2270 and provide feedback to the user. The provided feedback may be visual, audible, or haptic feedback. In some implementations, processor(s) 2210 may include one or more GPUs that may execute virtual reality engine 2226.

The methods, systems, and devices discussed above are examples. Various embodiments may omit, substitute, or add various procedures or components as appropriate. For instance, in alternative configurations, the methods described may be performed in an order different from that described, and/or various stages may be added, omitted, and/or combined. Also, features described with respect to certain embodiments may be combined in various other embodiments. Different aspects and elements of the embodiments may be combined in a similar manner. Also, technology evolves and, thus, many of the elements are examples that do not limit the scope of the disclosure to those specific examples.

Specific details are given in the description to provide a thorough understanding of the embodiments. However, embodiments may be practiced without these specific details. For example, well-known circuits, processes, systems, structures, and techniques have been shown without unnecessary detail in order to avoid obscuring the embodiments. This description provides example embodiments only, and is not intended to limit the scope, applicability, or configuration of the invention. Rather, the preceding description of the embodiments will provide those skilled in the art with an enabling description for implementing various embodiments. Various changes may be made in the function and arrangement of elements without departing from the spirit and scope of the present disclosure.

Also, some embodiments were described as processes depicted as flow diagrams or block diagrams. Although each may describe the operations as a sequential process, many of the operations may be performed in parallel or concurrently. In addition, the order of the operations may be rearranged. A process may have additional steps not included in the figure. Furthermore, embodiments of the methods may be implemented by hardware, software, firmware, middleware, microcode, hardware description languages, or any combination thereof.

Terms, “and” and “or” as used herein, may include a variety of meanings that are also expected to depend at least in part upon the context in which such terms are used. Typically, “or” if used to associate a list, such as A, B, or C, is intended to mean A, B, and C, here used in the inclusive sense, as well as A, B, or C, here used in the exclusive sense. In addition, the term “one or more” as used herein may be used to describe any feature, structure, or characteristic in the singular or may be used to describe some combination of features, structures, or characteristics. However, it should be noted that this is merely an illustrative example and claimed subject matter is not limited to this example. Furthermore, the term “at least one of” if used to associate a list, such as A, B, or C, can be interpreted to mean A, B, C, or any combination of A, B, and/or C, such as AB, AC, BC, AA, ABC, AAB, AABBCCC, etc.

The specification and drawings are, accordingly, to be regarded in an illustrative rather than a restrictive sense. It will, however, be evident that additions, subtractions, deletions, and other modifications and changes may be made thereunto without departing from the broader spirit and scope as set forth in the claims. Thus, although specific embodiments have been described, these are not intended to be limiting. Various modifications and equivalents are within the scope of the following claims.

What is claimed is:

1. A light source comprising an array of core-shell nanowire micro-light emitting diodes (micro-LEDs), each core-shell nanowire micro-LED of the array of core-shell nanowire micro-LEDs comprising:
a first semiconductor epitaxial layer including a nanowire core formed therein;
a first dielectric material layer in physical contact with and surrounding sidewalls of a bottom portion of the nanowire core, or in physical contact with a bottom surface of the nanowire core;
a second dielectric material layer in physical contact with a top surface of the nanowire core;
active layers grown only on sidewalls of the nanowire core, wherein the active layers are configured to emit visible light; and
a second semiconductor layer grown on the active layers, wherein the nanowire core and the second semiconductor layer are oppositely doped.

2. The light source of claim 1, wherein:
a pitch of the array of core-shell nanowire micro-LEDs is equal to or less than 2 μm; and
a width of the nanowire core is equal to or less than 1 μm.

3. The light source of claim 1, wherein a width of the nanowire core is equal to or less than 0.5 μm.

4. The light source of claim 1, further comprising a layer of a high-refractive index material on sidewalls of the second semiconductor layer, the high-refractive index material characterized by a refractive index greater than a refractive index of the second semiconductor layer.

5. The light source of claim 1, wherein a doping density of the nanowire core is less than 1×10²⁰ cm⁻³.

6. The light source of claim 1, wherein:
the first dielectric material layer includes SiO2 or SiN; and
the second dielectric material layer includes SiN.

7. The light source of claim 1, wherein the sidewalls of the nanowire core are on m-planes.

8. The light source of claim 1, wherein a cross-section of the nanowire core is characterized by a hexagonal shape or a circular shape.

9. The light source of claim 1, wherein the sidewalls of the nanowire core are on semipolar planes.

10. The light source of claim 1, wherein:
a first group of core-shell nanowire micro-LEDs of the array of core-shell nanowire micro-LEDs are configured to emit blue light; and
a second group of core-shell nanowire micro-LEDs of the array of core-shell nanowire micro-LEDs are configured to emit green light.

11. The light source of claim 10, wherein a third group of core-shell nanowire micro-LEDs of the array of core-shell nanowire micro-LEDs are configured to emit red light.

12. The light source of claim 1, wherein nanowire cores of the array of core-shell nanowire micro-LEDs are characterized by a same height.

13. The light source of claim 1, wherein a height of the active layers is less than a half of a height of the nanowire core.

14. A method of fabricating core-shell nanowire micro-light emitting diodes (micro-LEDs), the method comprising:
growing a first semiconductor layer on a substrate;
forming etch masks on the first semiconductor layer;
etching the first semiconductor layer using the etch masks to form a plurality of nanowire cores under the etch masks;
forming a dielectric material layer in regions between nanowire cores of the plurality of nanowire cores;
growing, with the etch masks on top of the plurality of nanowire cores, active layers on sidewalls of the plurality of nanowire cores, the active layers configured to emit visible light; and
growing, with the etch masks on top of the plurality of nanowire cores, a second semiconductor layer on surfaces of the active layers, wherein the first semiconductor layer and the second semiconductor layer are doped oppositely, and, in combination with the plurality of nanowire cores, form an array of core-shell nanowire micro-LEDs.

15. The method of claim 14, further comprising, before growing the active layers on the sidewalls of the plurality of nanowire cores, treating the sidewalls of the plurality of nanowire cores using KOH or tetramethyl ammonium hydroxide (TMAH).

16. The method of claim 14, further comprising depositing a layer of a high-refractive index material on sidewalls of the second semiconductor layer, the high-refractive index material characterized by a refractive index greater than a refractive index of the second semiconductor layer.

17. The method of claim 14, wherein growing the active layers on the sidewalls of the plurality of nanowire cores and growing the second semiconductor layer on the surfaces of the active layers comprise:
applying a first mask layer on a first set of nanowire cores of the plurality of nanowire cores;
growing first active layers on sidewalls of a second set of nanowire cores of the plurality of nanowire cores, the first active layers configured to emit light in a first wavelength range;
growing the second semiconductor layer on surfaces of the first active layers;
removing the first mask layer;
applying a second mask layer on surfaces of the second semiconductor layer grown on the surfaces of the first active layers;
growing second active layers on sidewalls of the first set of nanowire cores of the plurality of nanowire cores, the second active layers configured to emit light in a second wavelength range; and
growing the second semiconductor layer on surfaces of the second active layers.

18. The method of claim 14, wherein growing the first semiconductor layer includes epitaxial lateral overgrowth through a growth mask layer.

19. The method of claim 14, wherein forming the dielectric material layer in the regions between the nanowire cores of the plurality of nanowire cores comprises:
conformally depositing a layer of a dielectric material on surfaces of the first semiconductor layer;
spin-coating a photoresist layer on the layer of the dielectric material;
ashing the photoresist layer to leave photoresist only in the regions between the nanowire cores of the plurality of nanowire cores; and
etching the layer of the dielectric material using the photoresist in the regions between the nanowire cores of the plurality of nanowire cores as a mask layer.

20. The method of claim 14, wherein forming the dielectric material layer in the regions between the nanowire cores of the plurality of nanowire cores comprises:
depositing a layer of a dielectric material to fill the regions between the nanowire cores of the plurality of nanowire cores; and
etching the layer of the dielectric material using the etch masks on top of the plurality of nanowire cores.
